(19) United States
(12) Patent Application Publication
(10) Pub. No.: US 2017/0025817 A1
(43) Pub. Date: Jan. 26, 2017

(54) SEMICONDUCTOR LASER DEVICE, OPTICAL AMPLIFIER, AND METHOD OF DETECTING A SIGN OF SUDDEN FAILURE OF SEMICONDUCTOR LASER DEVICE

(71) Applicant: FUJITSU LIMITED, Kawasaki-shi (JP)

(72) Inventor: Miki ONAKA, Kawasaki (JP)

(73) Assignee: FUJITSU LIMITED, Kawasaki-shi (JP)

(21) Appl. No.: 15/285,821

(22) Filed: Oct. 5, 2016

Related U.S. Application Data
(63) Continuation of application No. 14/537,438, filed on Nov. 10, 2014.

(30) Foreign Application Priority Data
Dec. 13, 2013 (JP) 2013-258689

(51) Int. Cl. H01S 5/068; H01S 3/16; H01S 3/0941; H01S 5/343; H01S 3/094

(52) U.S. Cl. CPC H01S 5/06825; H01S 5/3432; H01S 3/094003; H01S 3/0941; H01S 3/1608; H01S 2301/02

(57) ABSTRACT

A semiconductor laser device includes: a semiconductor laser that contains aluminum or gallium arsenide in an active layer; a detector that detects a shift of a wavelength of emission light from the semiconductor laser toward a short wavelength side; and a judger that makes a judgment about a sign of a sudden failure of the semiconductor laser based on a detection result by the detector.

### CROSS-REFERENCE TO RELATED APPLICATION

This application is a continuation of U.S. application Ser. No. 14/537,438, filed Nov. 10, 2014, which is based upon and claims the benefit of priority of the prior Japanese Patent Application No. 2013-258689, filed on Dec. 13, 2013, the entire contents of which are incorporated herein by reference.

### FIELD

The embodiments discussed herein are related to a semiconductor laser device, an optical amplifier, and a method of detecting a sign of sudden failure of a semiconductor laser device.

### BACKGROUND

In recent years, a high-speed internet access service such as a fiber to the home (FTTH) service has been widely used. In the FTTH service, a passive optical network (PON) in which a single optical fiber is shared by a plurality of users has been known, for example. Further, in a submarine cable system, a device has been known that uses an optical filter that transmits light of a prescribed wavelength band to monitor an optical wavelength of a semiconductor laser.

However, related art has difficulty in an early prediction of a sign of a sudden failure in which a semiconductor optical device such as a semiconductor laser or a semiconductor optical amplifier suddenly degrades and stops operating.

Examples of optical devices may include a Fabry-Perot semiconductor laser, a vertical cavity surface emitting laser (VCSEL), a 0.98 μm pump laser, a semiconductor optical amplifier (SOA), and so forth. More specifically, examples of related art may preferably be applied to cases where an active layer contains Al (for example, AlGaAs or AlGaInAs) and where a material of the active layer is GaAs and that are in general said to be likely to cause a failure mode that is a sudden failure.

The following is a reference document:

[Document 1] Japanese Laid-open Patent Publication No. 10-9961.

### SUMMARY

According to an aspect of the invention, a semiconductor laser device includes: a semiconductor laser that contains aluminum or gallium arsenide in an active layer; a detector that detects a shift of a wavelength of emission light from the semiconductor laser toward a short wavelength side; and a judger that makes a judgment about a sign of a sudden failure of the semiconductor laser based on a detection result by the detector.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1A illustrates an example of a semiconductor laser device according to a first embodiment;

FIG. 1B illustrates an example of flows of light and electricity in the semiconductor laser device illustrated in FIG. 1A;

FIG. 2A illustrates a modification example of the semiconductor laser device illustrated in FIG. 1A;

FIG. 2B illustrates an example of flows of light and electricity in the semiconductor laser device illustrated in FIG. 2A;

FIG. 3A illustrates an example of an optical amplifier according to a first embodiment;

FIG. 3B illustrates an example of flows of light and electricity in the optical amplifier illustrated in FIG. 3A;

FIG. 4A illustrates a modification example of the optical amplifier illustrated in FIG. 3A;

FIG. 4B illustrates an example of flows of light and electricity in the optical amplifier illustrated in FIG. 4A;

FIG. 5A illustrates another example (semiconductor optical amplifier) of the optical amplifier according to the first embodiment;

FIG. 5B illustrates an example of flows of light and electricity in the optical amplifier (semiconductor optical amplifier) illustrated in FIG. 5A;

FIG. 6A illustrates a modification example of the optical amplifier illustrated in FIG. 5A;

FIG. 6B illustrates an example of flows of light and electricity in the optical amplifier illustrated in FIG. 6A;

FIG. 7A illustrates an example of a judgment device according to a second embodiment;

FIG. 7B illustrates an example of flows of light and electricity in the judgment device illustrated in FIG. 7A;

FIG. 8A illustrates a modification example of the judgment device according to the second embodiment;

FIG. 8B illustrates an example of flows of light and electricity in the judgment device illustrated in FIG. 8A;

FIG. 9A illustrates an example of a wavelength transmission characteristic of an optical filter;

FIG. 9B illustrates a modification example of the wavelength transmission characteristic of the optical filter;

FIG. 10A illustrates an example of a shape of an energy band gap in an LD that has a GaInAsP-based crystalline layer;

FIG. 10B illustrates an example of a characteristic of the shape of the energy band gap in the LD that has the AlGaInAs-based crystalline layer;

FIG. 11 illustrates an example of a semiconductor laser;

FIG. 12 illustrates an example of the causation between crystal defects and a wavelength shift;

FIG. 13 is a diagram (part 1) that illustrates an example of the causation between an increase in a carrier density of an active layer and the wavelength shift;

FIG. 14 is a diagram (part 2) that illustrates an example of the causation between the increase in the carrier density of the active layer and the wavelength shift;

FIG. 15 illustrates an example of a dark line that occurs in the active layer of the LD;

FIG. 16 illustrates an example of an oscillation wavelength shift;

FIG. 17A illustrates an example of the relationship between oscillation light in an initial state and the wavelength transmission characteristic of the optical filter;

FIG. 17B illustrates another example of the relationship between the oscillation light in the initial state and the wavelength transmission characteristic of the optical filter;

FIG. 18 illustrates an example of a change in transmittance in the wavelength shift;

FIG. 19 illustrates an example of a decrease in received light power of a first PD due to the wavelength shift;

FIG. 20 illustrates an example of characteristics of portions with respect to the oscillation wavelength shift;

FIG. 21 illustrates an example of a dynamic range of a PD;

FIG. 22 is a diagram (part 1) that illustrates an example of a change in the oscillation wavelength in accordance with elapsed time;

FIG. 23 is a diagram (part 2) that illustrates an example of the change in the oscillation wavelength in accordance with the elapsed time;

FIG. 24 is a flowchart that illustrates an example of processing of the judgment device;

FIG. 25 illustrates an example of a communication system to which the judgment device is applied;

FIG. 26 illustrates an example of flows of light and electricity in the communication system illustrated in FIG. 25;

FIG. 27 illustrates a first modification example of an OLT;

FIG. 28 illustrates a second modification example of the OLT;

FIG. 29 illustrates an example of an optical amplifier according to a third embodiment;

FIG. 30 illustrates an example of flows of light and electricity in the optical amplifier illustrated in FIG. 29;

FIG. 31 illustrates an example of characteristics of the oscillation wavelengths in accordance with a temperature with respect to a drive current;

FIG. 32 illustrates an example of the relationship between the change in PD received light power in accordance with the elapsed time and the oscillation wavelength;

FIG. 33 illustrates an example of an LD chip that is capable of switching LDs;

FIG. 34 illustrates an example of flows of light and electricity in a configuration of the LD chip illustrated in FIG. 33;

FIG. 35 illustrates a modification example of the LD chip illustrated in FIG. 33;

FIG. 36 illustrates an example of flows of light and electricity in a configuration of the LD chip illustrated in FIG. 35;

FIG. 37 illustrates an example of a drive circuit and the LD chip;

FIG. 38 illustrates an example of flows of light and electricity in the drive circuit and the LD chip illustrated in FIG. 37;

FIG. 39 illustrates an example of an electric switch circuit;

FIG. 40 illustrates an example of an operation of a switching circuit of the electric switch circuit;

FIG. 41 illustrates an example of an optical amplifier according to a fourth embodiment;

FIG. 42 illustrates an example of flows of light and electricity in the optical amplifier illustrated in FIG. 41;

FIG. 43 illustrates a modification example of the optical amplifier according to the fourth embodiment;

FIG. 44 illustrates an example of flows of light and electricity in the optical amplifier illustrated in FIG. 43;

FIG. 45 illustrates an example of signal light and ASE light in an SOA; and

FIG. 46 illustrates an example of the change in transmittance in the wavelength shift.

### DESCRIPTION OF EMBODIMENTS

Embodiments of a semiconductor laser device, an optical amplifier, and a judgment method of this disclosure will hereinafter be described in detail with reference to drawings.

### First Embodiment

### Semiconductor Laser Device According to First Embodiment

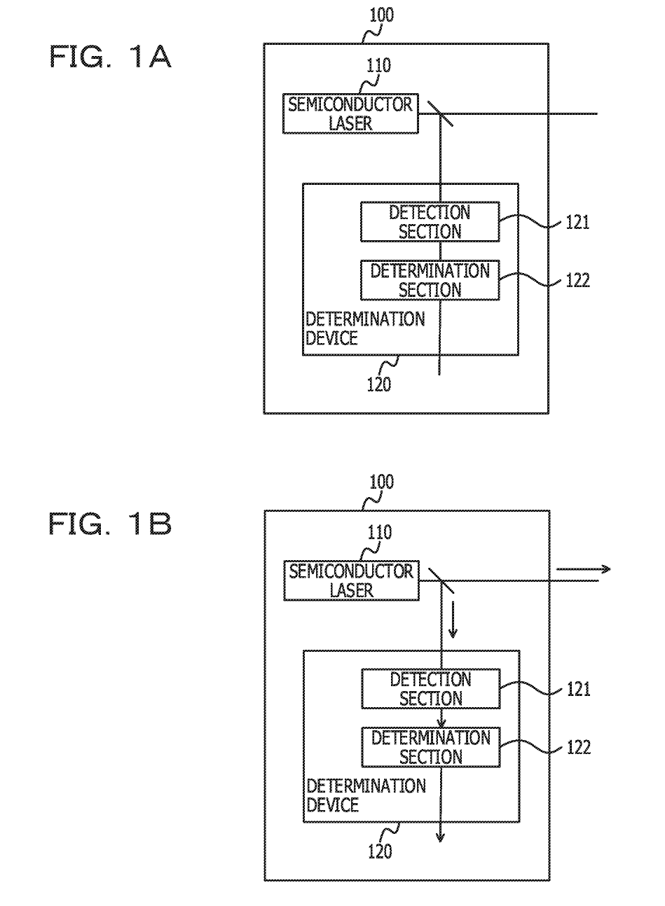

FIG. 1A illustrates an example of a semiconductor laser device according to the first embodiment. FIG. 1B illustrates an example of flows of light and electricity in the semiconductor laser device illustrated in FIG. 1A. As illustrated in FIGS. 1A and 1B, a semiconductor laser device 100 according to the first embodiment includes a semiconductor laser 110 and a judgment device 120.

The semiconductor laser 110 is a laser diode (LD) that contains aluminum (Al) or gallium arsenide (GaAs). The semiconductor laser 110 oscillates and emits light that corresponds to an input drive current.

The judgment device 120 makes a judgment about a sign of a sudden failure of the semiconductor laser 110. Emission light from the semiconductor laser 110 is incident on the judgment device 120. FIGS. 1A and 1B illustrate a configuration in which forward emission light from the semiconductor laser 110 is split and is incident on the judgment device 120. However, a configuration is possible in which backward emission light (backward light) from the semiconductor laser 110 is incident on the judgment device 120.

The judgment device 120 includes a detection section 121 and a judgment section 122, for example. The detection section 121 detects a shift of a wavelength of the emission light from the semiconductor laser 110 toward a short wavelength side in accordance with elapsed time. The detection section 121 then outputs a detection result to the judgment section 122.

The judgment section 122 makes a judgment of presence or absence of the sign of the sudden failure of the semiconductor laser 110 based on the detection result that is output from the detection section 121. The judgment section 122 then outputs a judgment result. For example, the judgment section 122 outputs the judgment result to a maintainer of the semiconductor laser 100. Alternatively, the judgment section 122 may output the judgment result to a control circuit or the like of the semiconductor laser 110, for example.

Further, the judgment device 120 may be provided in a device other than the semiconductor laser 110. For example, the judgment device 120 may be provided in a relay device that relays signal light transmitted by the semiconductor laser 110 or an optical reception device that receives the signal light transmitted by the semiconductor laser 110.

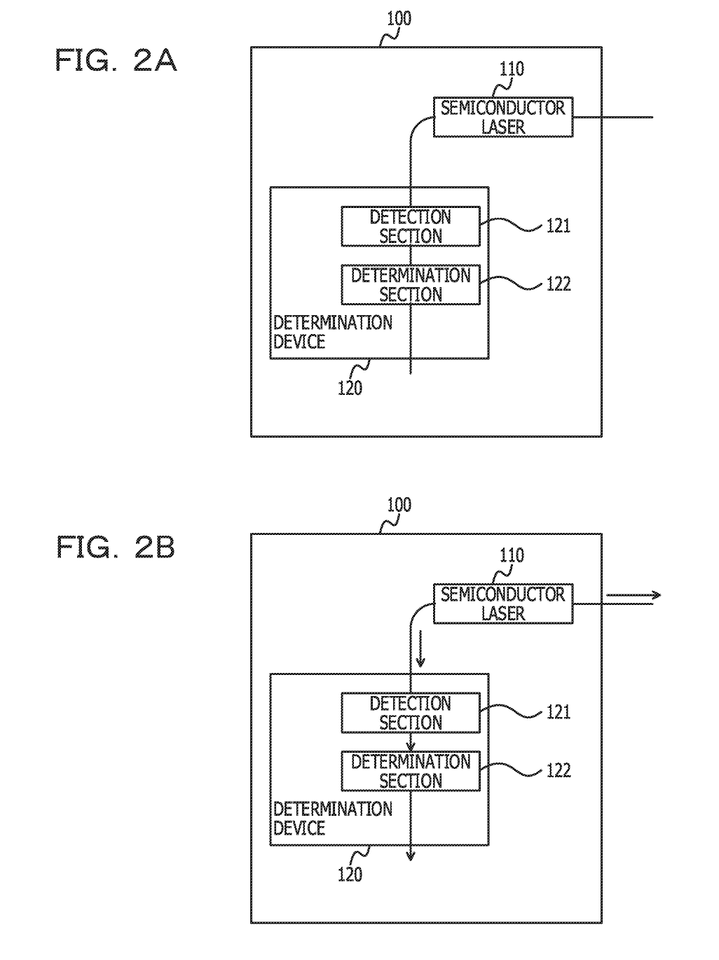

FIG. 2A illustrates a modification example of the semiconductor laser device illustrated in FIG. 1A. FIG. 2B illustrates an example of flows of light and electricity in the semiconductor laser device illustrated in FIG. 2A. In FIGS. 2A and 2B, the same reference numerals are provided to configurations that are the same as FIGS. 1A and 1B, and a description thereof will not be made. As illustrated in FIGS. 2A and 2B, the semiconductor laser device 100 may also have a configuration in which the backward emission light (backward light) from the semiconductor laser 110 is incident on the judgment device 120. A short wave shift may thereby be monitored without splitting the forward emission light (forward light) of the semiconductor laser 110.

(Optical Amplifier According to First Embodiment)

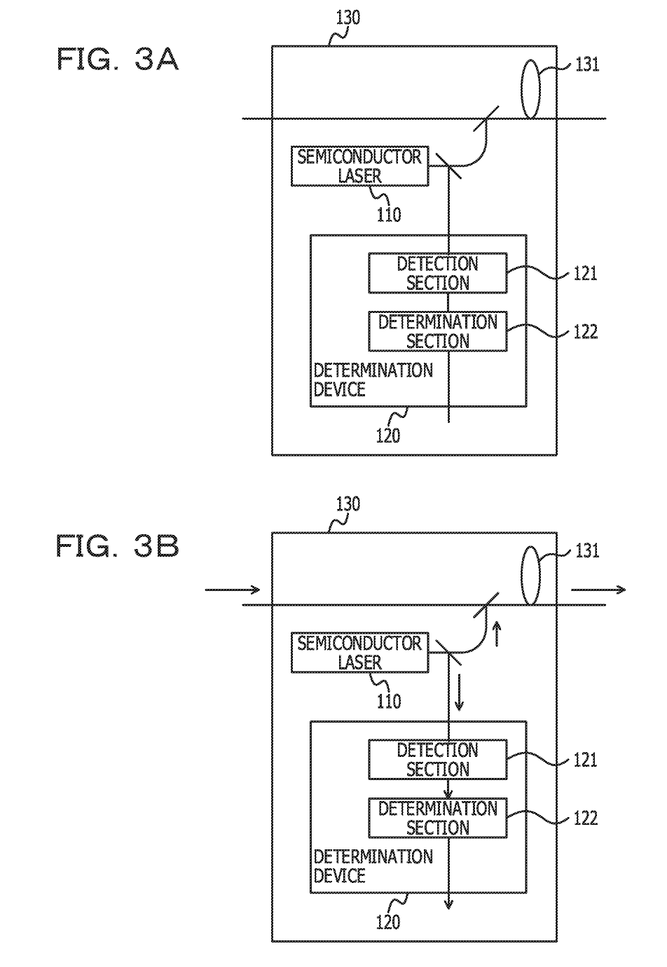

FIG. 3A illustrates an example of an optical amplifier according to the first embodiment. FIG. 3B illustrates an example of flows of light and electricity in the optical amplifier illustrated in FIG. 3A. In FIGS. 3A and 3B, the same reference numerals are provided to portions that are the same as the ones illustrated in FIGS. 1A and 1B, and a description thereof will not be made. As illustrated in FIGS. 3A and 3B, an optical amplifier 130 according to the first embodiment includes the semiconductor laser 110, the judgment device 120, and an optical gain medium 131.

The optical gain medium 131 allows incident light on the optical amplifier 130 and the emission light from the semiconductor laser 110 to pass through and thereby amplifies and emits the incident light on the optical amplifier 130. The optical gain medium 131 is an erbium doped fiber (EDF), for example.

FIGS. 3A and 3B illustrate a forward pumping configuration in which the incident light on the optical amplifier 130 and the emission light from the semiconductor laser 110 are multiplexed and are incident from a front stage of the optical gain medium 131. In contrast, for example, a backward pumping configuration is also possible in which the incident light on the optical amplifier 130 is incident from the front stage of the optical gain medium 131 and the emission light from the semiconductor laser 110 is incident from a rear stage of the optical gain medium 131. Further, a bi-directional pumping configuration that combines the forward pumping and the backward pumping is also possible.

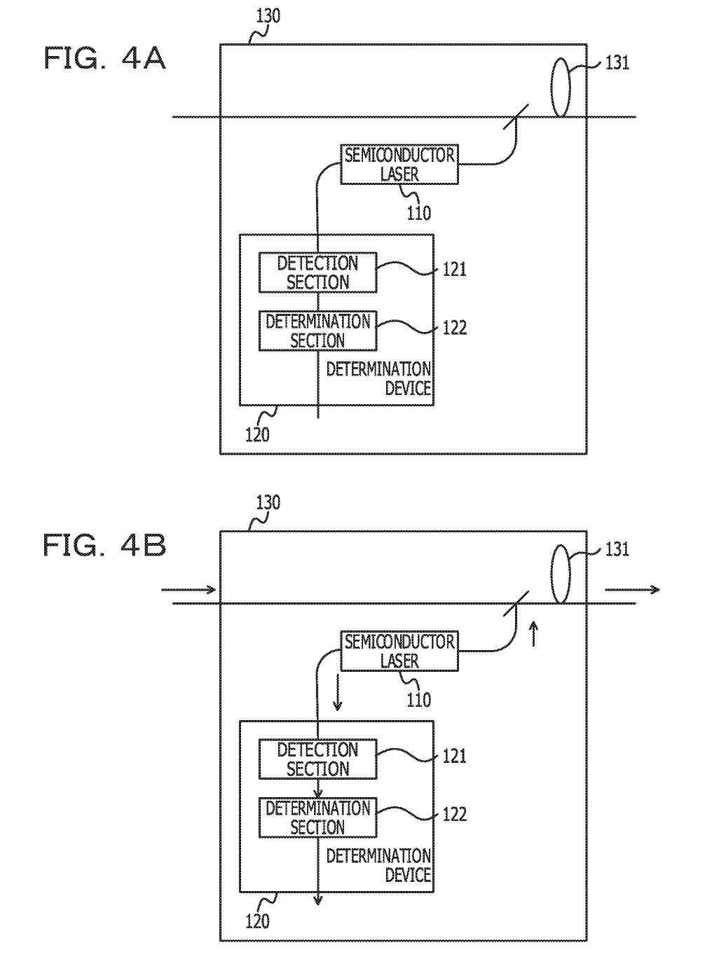

FIG. 4A illustrates a modification example of the optical amplifier illustrated in FIG. 3A. FIG. 4B illustrates an example of flows of light and electricity in the optical amplifier illustrated in FIG. 4A. In FIGS. 4A and 4B, the same reference numerals are provided to configurations that are the same as FIGS. 3A and 3B, and a description thereof will not be made. As illustrated in FIGS. 4A and 4B, the optical amplifier 130 may also have a configuration in which the backward emission light (backward light) from the semiconductor laser 110 is incident on the judgment device 120. A short wave shift may thereby be monitored without splitting the forward emission light (forward light) of the semiconductor laser 110.

(Another Example of Optical Amplifier According to First Embodiment)

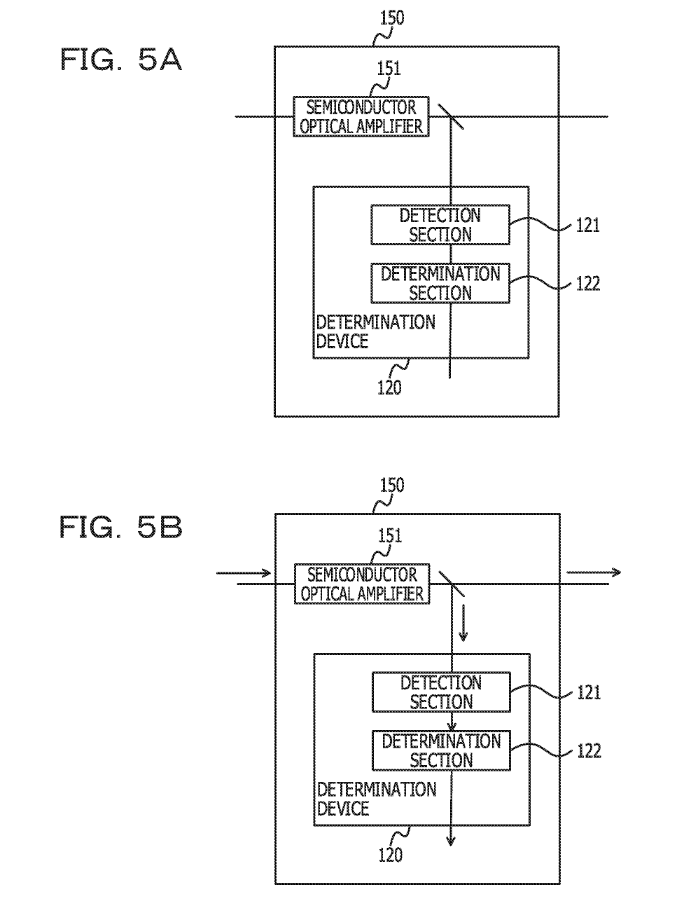

FIG. 5A illustrates another example (semiconductor optical amplifier) of the optical amplifier according to the first embodiment. FIG. 5B illustrates an example of flows of light and electricity in the optical amplifier (semiconductor optical amplifier) illustrated in FIG. 5A. In FIGS. 5A and 5B, the same reference numerals are provided to portions that are the same as the ones illustrated in FIGS. 1A and 1B, and a description thereof will not be made. As illustrated in FIGS. 5A and 5B, an optical amplifier 150 according to the first embodiment includes a semiconductor optical amplifier 151 and the judgment device 120.

The semiconductor optical amplifier 151 contains aluminum or gallium arsenide in an active layer, for example. Because the semiconductor optical amplifier uses the principle of stimulated emission of laser similarly to the semiconductor laser, there is a risk of the sudden failure similarly to the semiconductor laser. Further, in a case where the active layer contains aluminum, efficiency (drive current to optical output power) at a high temperature may be improved similarly to the semiconductor laser. However, aluminum is likely to bond to oxygen and thus becomes a factor in acceleration of an increase of crystal defects, thus increasing the risk of the sudden failure.

For example, the semiconductor optical amplifier 151 is an SOA. The semiconductor optical amplifier 151 amplifies and emits light that is incident thereon in accordance with the input drive current. Further, amplified spontaneous emission (ASE) light is emitted from the semiconductor optical amplifier 151.

The judgment device 120 makes a judgment about the sign of the sudden failure of the semiconductor optical amplifier 151. The ASE light from the semiconductor optical amplifier 151 is incident on the judgment device 120. FIGS. 5A and 5B illustrate a configuration in which the forward emission light from the semiconductor optical amplifier 151 is split and is incident on the judgment device 120. However, a configuration is possible in which the backward emission light (backward light) from the semiconductor optical amplifier 151 is incident on the judgment device 120.

The detection section 121 detects the shift of the wavelength of the ASE light from the semiconductor optical amplifier 151 toward the short wavelength side. The judgment section 122 makes a judgment of presence or absence of the sign of the sudden failure of the semiconductor optical amplifier 151 based on a detection result that is output from the detection section 121.

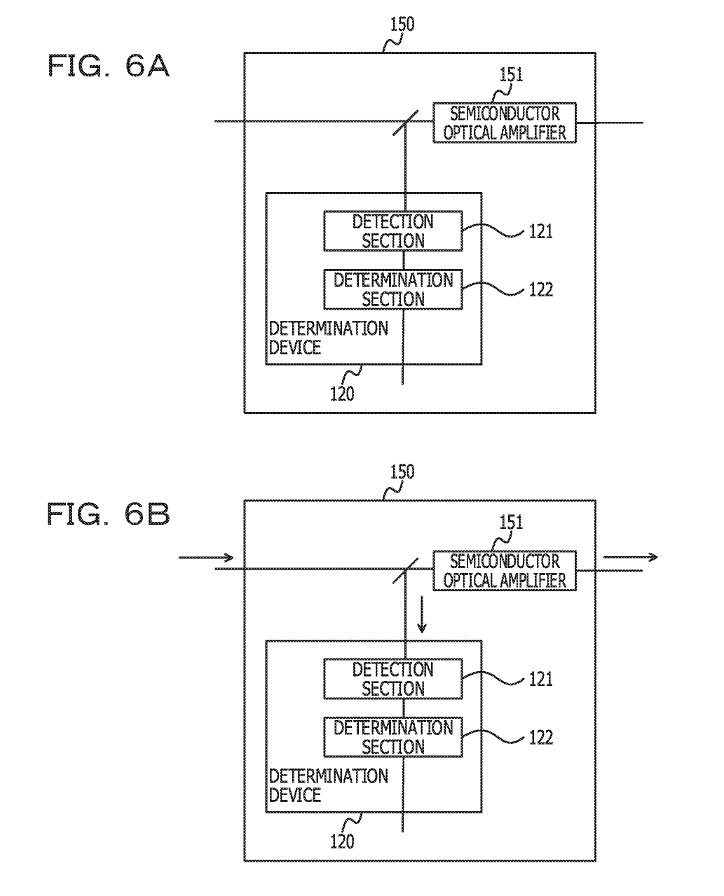

FIG. 6A illustrates a modification example of the optical amplifier illustrated in FIG. 5A. FIG. 6B illustrates an example of flows of light and electricity in the optical amplifier illustrated in FIG. 6A. In FIGS. 6A and 6B, the same reference numerals are provided to portions that are the same as the ones illustrated in FIGS. 5A and 5B, and a description thereof will not be made. As illustrated in FIGS. 6A and 6B, the optical amplifier 150 may also have a configuration in which the backward emission light (backward light) from the semiconductor optical amplifier 151 is incident on the judgment device 120. The short wave shift may thereby be monitored without splitting the forward emission light (forward light) of the semiconductor optical amplifier 151.

As described above, the first embodiment enables detection of the shift of an output wavelength toward the short wavelength side that appears as the sign of the sudden failure in an early stage in the semiconductor laser 110 and the semiconductor optical amplifier 151 that contain aluminum or gallium arsenide in the active layers, for example. This enables an early prediction of the sudden failure of semiconductor optical devices such as the semiconductor laser 110 and the semiconductor optical amplifier 151. The early prediction of the sudden failure of the semiconductor optical device is enabled, and switching or the like of apparatuses prior to the sudden failure is thereby enabled, for example.

(Example of Detection Method of Wavelength Shift)

The detection section 121 obtains a value that corresponds to a shift amount of the wavelength of the emission light (or the ASE light) from an initial state toward the short wavelength side, for example. The value that corresponds to the shift amount of the wavelength may be a value that directly or indirectly represents the shift amount of the wavelength or may be a value that increases or decreases in response to the shift amount of the wavelength, for example. Accordingly, in a case where the wavelength of the emission light (or the ASE light) shifts from the initial state toward the short wavelength side to some extent, a judgment may be made that there is the sign of the sudden failure of the semiconductor laser 110 or the semiconductor optical amplifier 151.

Further, the detection section 121 may obtain a value that corresponds to the shift amount of the wavelength of the emission light (or the ASE light) toward the short wavelength side for a unit time. Accordingly, in a case where the wavelength of the emission light (or the ASE light) rapidly shifts toward the short wavelength side, a judgment may be made that there is the sign of the sudden failure of the semiconductor laser 110 or the semiconductor optical amplifier 151.

Further, the judgment device 120 may include an information collector that obtains information that indicates a temperature of the semiconductor laser 110 or the semiconductor optical amplifier 151. The detection section 121 then detects the shift of the wavelength of the emission light (or the ASE light) toward the short wavelength side, which is corrected based on temperature information that is obtained by the information collector. Accordingly, even in a case where there is the shift of the wavelength of the emission light (or the ASE light) due to a fluctuation of the temperature of the semiconductor laser 110 or the semiconductor optical amplifier 151, the shift of the wavelength toward the short wavelength side as the sign of the sudden failure due to an active layer material or the like that is subject to increases in oxidation of aluminum and crystal defects may be detected with high accuracy. This enables the judgment about the sign of the sudden failure with high accuracy.

Further, the judgment device 120 may include an information collector that obtains information that indicates a magnitude of the drive current or the temperature of the semiconductor laser 110 or the semiconductor optical amplifier 151. The detection section 121 then detects the shift of the wavelength of the emission light (or the ASE light) toward the short wavelength side, which is corrected based on magnitude information of the drive current or the temperature that is obtained by the information collector. Accordingly, even in a case where there is the shift of the wavelength of the emission light (or the ASE light) due to a fluctuation of the magnitude of the drive current or the temperature of the semiconductor laser 110 or the semiconductor optical amplifier 151, the shift of the wavelength toward the short wavelength side as the sign of the sudden failure due to oxidation of aluminum or the like may be detected with high accuracy. This enables the judgment about the sign of the sudden failure with high accuracy.

(Operation in Detection of Sign of Sudden Failure)

Further, for example, the semiconductor laser device 100 or the optical amplifier 130 may include the plurality of semiconductor lasers 110. The plurality of semiconductor laser 110 may individually be formed as separate chips or may be formed by providing a plurality of terminals and active layers in a single chip. In addition, the semiconductor laser device 100 or the optical amplifier 130 may include a control section that switches the semiconductor lasers to be driven among the plurality of semiconductor lasers 110 in a case where the judgment section 122 determines that the sign of the sudden failure is present.

Accordingly, the semiconductor lasers 110 to be used are switched in a case where the sign of the sudden failure is detected in the semiconductor lasers that are being used among the plurality of semiconductor lasers 110, and an interruption of transmission of an optical signal (system down) may thereby be avoided. However, the configuration of the semiconductor laser device 100 or the optical amplifier 130 is not limited to such a redundant configuration but may be a configuration that includes the single semiconductor laser 110.

Further, the optical amplifier 150 may include the plurality of semiconductor optical amplifiers 151 in a similar manner. The plurality of semiconductor optical amplifiers 151 may individually be formed as separate chips or may be formed by providing a plurality of terminals and active layers in a single chip. In addition, the optical amplifier 150 may include a control section that switches the semiconductor optical amplifiers to be driven among the plurality of semiconductor optical amplifiers 151 in a case where the judgment section 122 determines that the sign of the sudden failure is present.

Accordingly, the semiconductor optical amplifiers to be used are switched in a case where the sign of the sudden failure is detected in the semiconductor optical amplifiers that are being used among the plurality of semiconductor optical amplifiers 151, and the interruption of transmission of the optical signal (system down) may thereby be avoided. However, the configuration of the optical amplifier 150 is not limited to such a redundant configuration but may be a configuration that includes the single semiconductor optical amplifier 151.

(Other Semiconductor Optical Devices)

A description is made about the judgment about the sign of the sudden failure of the LD and the SOA in a case where the active layer contains aluminum or the material of the active layer is gallium arsenide. However, semiconductor optical devices that are targets of the above-described judgment method are not limited to the LD and the SOA that contain aluminum or gallium arsenide in the active layer. For example, the above-described judgment method may be used for a semiconductor optical device which contains a material that may become a factor in disorganization of a crystal periodic structure due to aging degradation and in which the wavelength of the output light shifts toward the short wavelength side in response to the disorganization of the crystal periodic structure.

### Second Embodiment

### Judgment Device According to Second Embodiment

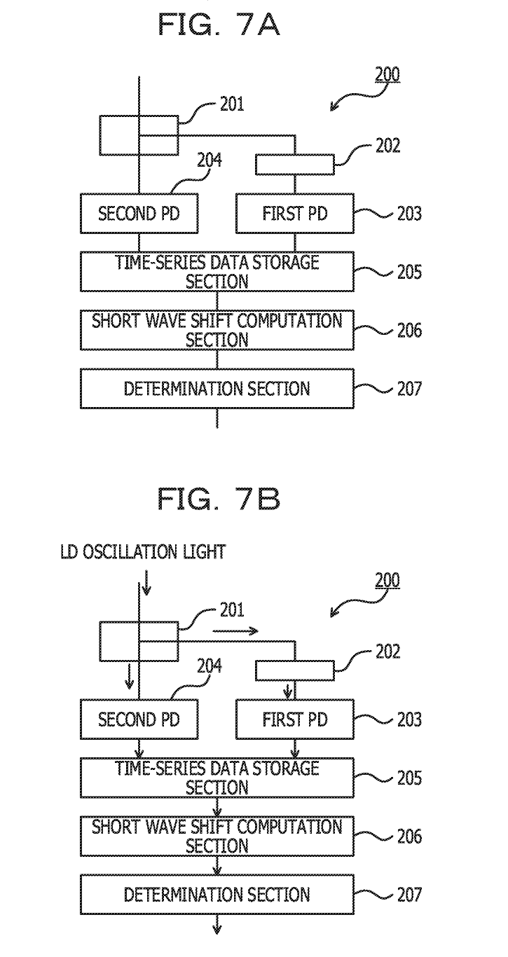

FIG. 7A illustrates an example of a judgment device according to the second embodiment. FIG. 7B illustrates an example of flows of light and electricity in the judgment device illustrated in FIG. 7A. As illustrated in FIGS. 7A and 7B, a judgment device 200 according to the second embodiment includes an optical branch unit 201, an optical filter 202, a first PD 203, a second PD 204, a time-series data storage section 205, a short wave shift computation section 206, and a judgment section 207.

The judgment device 120 illustrated in FIGS. 1A to 6B may be realized by the judgment device 200, for example. The detection section 121 illustrated in FIGS. 1A to 6B may be realized by the time-series data storage section 205 and the short wave shift computation section 206, for example. The judgment section 122 illustrated in FIGS. 1A to 6B may be realized by the judgment section 207, for example.

The judgment device 200 makes a judgment of presence or absence of the sign of the sudden failure of the LD that contains aluminum or gallium arsenide in the active layer, for example. Oscillation light (LD oscillation light) of the LD as a judgment target of the judgment device 200 is input to the optical branch unit 201. The optical branch unit 201 splits the input light and outputs beams of the split light to the optical filter 202 and the second PD 204.

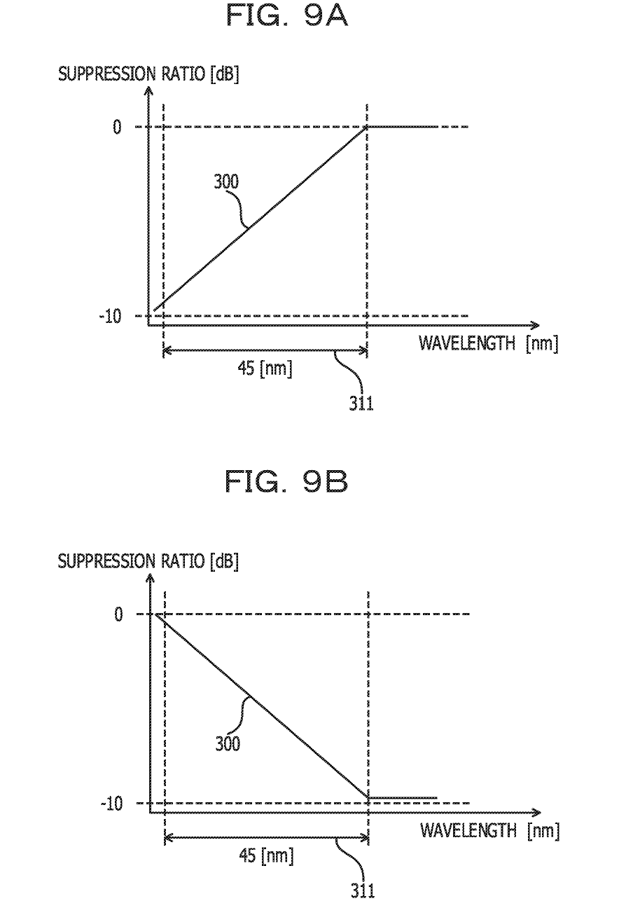

The optical filter 202 transmits the light that is output from the optical branch unit 201 by a characteristic of transmitting prescribed wavelengths and outputs the transmitted light to the first PD 203. A wavelength transmission characteristic of the optical filter 202 provides different transmittances for an oscillation wavelength of the LD as the judgment target in an initial state and for a shorter wavelength than the oscillation wavelength in the initial state (for example, see FIG. 9A). The optical filter 202 may be realized by a dielectric multilayer film or a fiber grating, for example. A filter of a wide band (for example, 40 nm) compared to a band-pass filter of a common band (for example, 1 nm) may be used for the optical filter 202, for example.

The second photo detector (PD) 204 receives the light that is output from the optical branch unit 201 and outputs an electric signal that corresponds to power of the received light to the time-series data storage section 205. The first PD 203 receives the light that is output from the optical filter 202 and outputs an electric signal that corresponds to power of the received light to the time-series data storage section 205.

The time-series data storage section 205 stores time-series data of a ratio of the electric signals that are output from the first PD 203 and the second PD 204. The ratio of the electric signals that are output from the first PD 203 and the second PD 204 changes in accordance with the shift amount of the oscillation wavelength of the LD as the judgment target of the judgment device 200 toward the short wavelength side.

The short wave shift computation section 206 performs computation of a shift state of the oscillation wavelength of the LD as the judgment target of the judgment device 200 toward the short wavelength side based on the time-series data that are stored in the time-series data storage section 205. Examples of the computation of the shift state are calculation of a value that corresponds to a fluctuation amount of the shift amount from the initial state, computation of a value that corresponds to a change amount of the shift amount for a unit time, and the like. The short wave shift computation section 206 then outputs a computation result of the shift amount to the judgment section 207.

The judgment section 207 makes a judgment of presence or absence of the sign of the sudden failure of the LD as the judgment target of the judgment device 200 based on the computation result that is output from the short wave shift computation section 206. The judgment section 207 outputs an alarm, for example, in a case where a judgment is made that the sign of the sudden failure of the LD is present.

For example, the judgment section 207 determines that the sign of the sudden failure of the LD is present in a case where the value that corresponds to the shift amount toward the short wavelength side for a unit time exceeds a prescribed value TH1. Further, the judgment section 207 determines that the sign of the sudden failure of the LD is present in a case where the change in the value that corresponds to the shift amount toward the short wavelength side from an initial value exceeds a prescribed value TH2 (for example, TH2<TH1).

The judgment device 200 illustrated in FIGS. 7A and 7B enables the detection of the shift of the oscillation wavelength of the LD toward the short wavelength side by using the optical filter 202 that has the characteristic of transmitting prescribed wavelengths and enables the judgment about the sign of the sudden failure of the LD based on the detection result.

Further, a comparison result of received light power between emission light of the LD that is transmitted through the optical filter 202 and emission light that is not transmitted through the optical filter 202 may be used. Accordingly, the shift of the oscillation wavelength of the LD toward the short wavelength side may be detected with high accuracy even in a case where the temperature, the drive current, and the like of the LD fluctuate. This enables the judgment about the sign of the sudden failure with high accuracy.

The time-series data storage section 205, the short wave shift computation section 206, and the judgment section 207 may be realized by digital circuits, for example. For example, a digital signal processor (DSP), a field programmable gate array (FPGA), or the like may be used for the digital circuits.

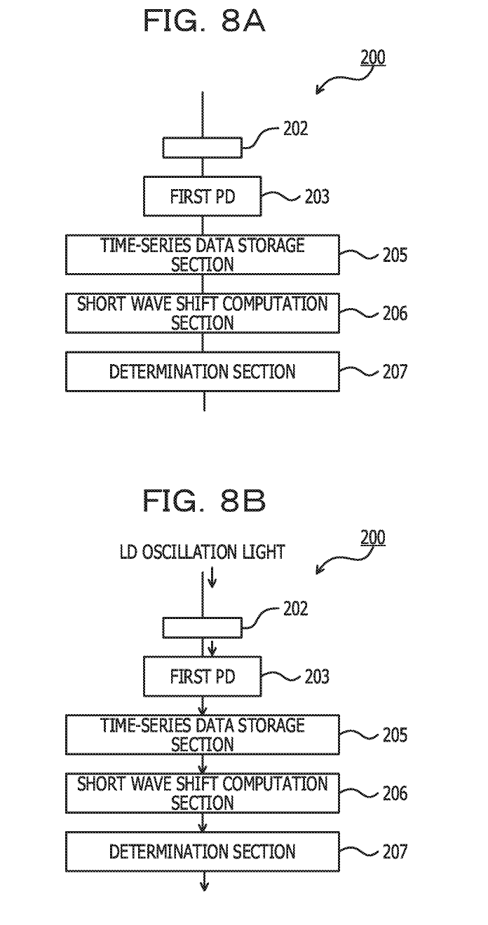

FIG. 8A illustrates a modification example of the judgment device according to the second embodiment. FIG. 8B illustrates an example of flows of light and electricity in the judgment device illustrated in FIG. 8A. In FIGS. 8A and 8B, the same reference numerals are provided to portions that are the same as the ones illustrated in FIGS. 7A and 7B, and a description thereof will not be made. As illustrated in FIGS. 8A and 8B, the judgment device 200 according to the second embodiment may have a configuration from which the optical branch unit 201 and the second PD 204 illustrated in FIGS. 7A and 7B are omitted.

In a configuration illustrated in FIGS. 8A and 8B, the oscillation light of the LD as the judgment target of the judgment device 200 is input to the optical filter 202. Further, the time-series data storage section 205 stores time-series data of the electric signal that is output from the first PD 203. The electric signal that is output from the first PD 203 changes in accordance with the shift amount of the oscillation wavelength of the LD as the judgment target of the judgment device 200 toward the short wavelength side.

The judgment device 200 illustrated in FIGS. 8A and 8B also enables the detection of the shift of the oscillation wavelength of the LD toward the short wavelength side by using the optical filter 202 that has the characteristic of transmitting prescribed wavelengths and enables the judgment about the sign of the sudden failure of the LD based on the detection result.

(Wavelength Transmission Characteristic of Optical Filter)

FIG. 9A illustrates an example of a wavelength transmission characteristic of an optical filter. In FIG. 9A, the horizontal axis represents wavelength [nm], and the vertical axis represents suppression ratio [dB]. The optical filter 202 illustrated in FIG. 7A has a wavelength transmission characteristic 300 illustrated in FIG. 9A, for example. The wavelength transmission characteristic 300 represents the suppression ratio (transmittance) with respect to the wavelength.

In an example illustrated in FIG. 9A, in the wavelength transmission characteristic 300, the transmittance continuously decreases toward the short wavelength side in a wavelength band 311 of 45 nm. Thus, the received light power at the first PD 203 decreases as the oscillation wavelength of the LD shifts toward the short wavelength side.

Accordingly, in a configuration illustrated in FIGS. 7A and 7B, for example, a decrease in a ratio of the received light power of the first PD 203 to the received light power of the second PD 204 is monitored, thereby enabling the detection of the shift of the oscillation wavelength of the LD toward the short wavelength side. Further, in the configuration illustrated in FIGS. 8A and 8B, a decrease in the received light power of the first PD 203 is monitored, thereby enabling the detection of the shift of the oscillation wavelength of the LD toward the short wavelength side.

The width of the wavelength band 311 (for example, 45 nm or wider) may be defined in consideration of a width due to a solid variation of the oscillation wavelength of the LD (for example, 30 nm), a width due to a shift toward the short wavelength side (for example, 10 nm), and a width that depends on the temperature and the current (for example, 3 nm).

Further, the suppression ratio in the wavelength band 311 may be increased in order to improve detection accuracy of a wavelength shift toward the short wavelength side. For example, the suppression ratio may be set to 10 dB or greater in a case of detecting the wavelength shift of 1 nm.

FIG. 9B illustrates a modification example of the wavelength transmission characteristic of the optical filter. In FIG. 9B, the same reference numerals are provided to portions that are the same as the ones illustrated in FIG. 9A, and a description thereof will not be made. As illustrated in FIG. 9B, in the wavelength transmission characteristic 300, the transmittance may continuously increase toward the short wavelength side in the wavelength band 311 of 45 nm. In this case, the received light power at the first PD 203 increases as the oscillation wavelength of the LD shifts toward the short wavelength side.

Accordingly, in the configuration illustrated in FIGS. 7A and 7B, for example, an increase in a ratio of the received light power of the first PD 203 to the received light power of the second PD 204 is monitored, thereby enabling the detection of the shift of the oscillation wavelength of the LD toward the short wavelength side. Further, conditions such as the temperature and the drive current, aging degradation, and the like may not be taken into account in the configuration of FIGS. 8A and 8B. Thus, although the detection accuracy is relatively low, a judgment reference value of a short wave shift amount that corresponds to the sign of the sudden failure is set to a relatively large value, and the increase in the received light power of the first PD 203 is monitored. It is of course possible to thereby detect the shift of the oscillation wavelength of the LD toward the short wavelength side.

As illustrated in FIGS. 9A and 9B, the optical filter 202 has the wavelength transmission characteristic in which the transmittance changes in an increasing direction or a decreasing direction as the wavelength becomes the shorter wavelength from an initial wavelength band of the LD to a short wavelength band. This enables a judgment of the magnitude of the shift of the oscillation wavelength of the LD from the power of light that is transmitted through the optical filter 202.

However, in the optical filter 202, it is sufficient that the transmittance in the initial wavelength band of the emission light of the LD is at least different from the transmittance in a shorter wavelength band than the initial wavelength band. This enables a judgment of presence or absence of the shift of the oscillation wavelength of the LD from the power of light that is transmitted through the optical filter 202.

A description will hereinafter be made about a case where the wavelength transmission characteristic of the optical filter 202 is the wavelength transmission characteristic 300 illustrated in FIG. 9A.

(Shape of Energy Band Gap in LD)

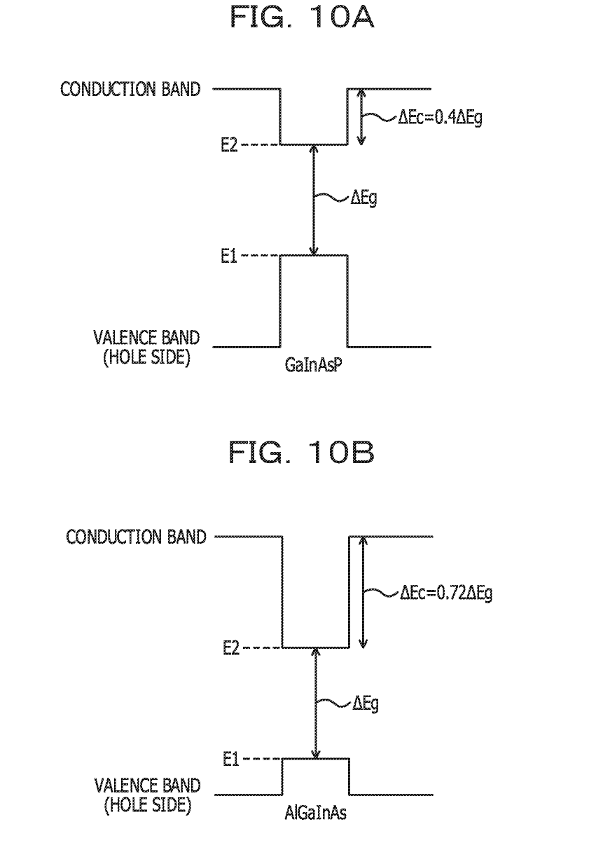

FIG. 10A illustrates an example of a shape of an energy band gap in the LD that has a GaInAsP-based crystalline layer. FIG. 10B illustrates an example of a characteristic of the shape of the energy band gap in the LD that has the AlGaInAs-based crystalline layer.

In FIGS. 10A and 10B, an energy band gap ΔEg is an energy band gap in the LD. The energy band gap ΔEg is the difference between excitation energy E1 of the valence band in the LD and excitation energy E2 of the conduction band (E2−E1). Further, the energy band gap ΔEg corresponds to the oscillation wavelength of the LD. In examples illustrated in FIGS. 10A and 10B, the energy band gap ΔEg is the same.

In FIGS. 10A and 10B, a depth of a quantum well ΔEc is the depth of the quantum well in the LD. In the LD that contains no aluminum in the active layer material, the depth of the quantum well is ΔEc=0.4 ΔEg as illustrated in FIG. 10A, for example. In the LD that contains aluminum or gallium arsenide in the active layer material, the depth of the quantum well is ΔEc=0.72 ΔEg as illustrated in FIG. 10B, for example.

As described above, electrons are strongly confined when aluminum (Al) is contained in the active layer material, thus enabling reduction of leakage of electrons from the quantum well at a high temperature. Accordingly, an LD with a good temperature characteristic may be realized. Further, non-uniform implantation in a hole with a large effective mass is less likely to occur because a band offset on the hole side is small. Accordingly, an LD that is suitable for high speed modulation may be realized.

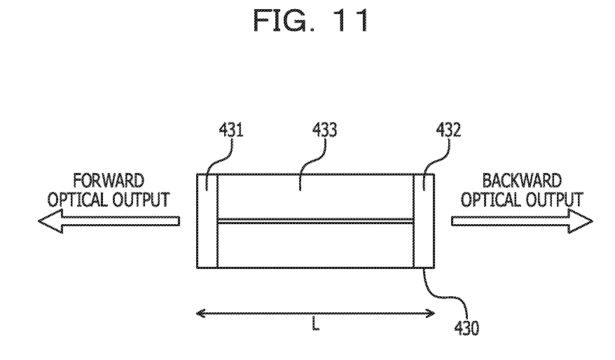

FIG. 11 illustrates an example of a semiconductor laser. A semiconductor laser 430 illustrated in FIG. 11, for example, may be used for the LD as the judgment target of the judgment device 200. The semiconductor laser 430 is a Fabry-Perot semiconductor laser, for example.

Mirrors 431 and 432 are provided on both sides of the semiconductor laser 430. An active layer 433 is the active layer of the semiconductor laser 430. A resonant length L is a resonant length of the active layer 433 and is an interval between the mirrors 431 and 432. A characteristic of laser oscillation may be expressed as the following equation (1), for example.

δ·G=αi+αm (1)

A term Γ is a constant that indicates a proportion of confinement of light in the semiconductor laser 430. A term G is a density of a carrier (carrier density) that is implanted in the active layer 433 and corresponds to a gain. A term αi is an internal loss in the active layer 433 of the semiconductor laser 430. A term am is a resonant mirror loss in the mirrors 431 and 432 of the semiconductor laser 430.

Above equation (1) may be converted into the following equation (2) with respect to the longitudinal direction of the active layer 433 of the semiconductor laser 430.

δ·(Gng·Lng+Gok·Lok)=αi·L+αm·L (2)

A term L is the resonant length of the active layer 433. Further, L=Lng+Lok. A term Lng is the length of a portion of the active layer 433 that does not emit light due to crystal defects. A term Lok is the length of a portion of the active layer 433 that normally emits light. A term Gng is the gain of a portion of the active layer 433 in which crystal defects are present. A term Gok is the gain of a portion of the active layer 433 that normally emits light.

(Causation Between Crystal Defect and Wavelength Shift)

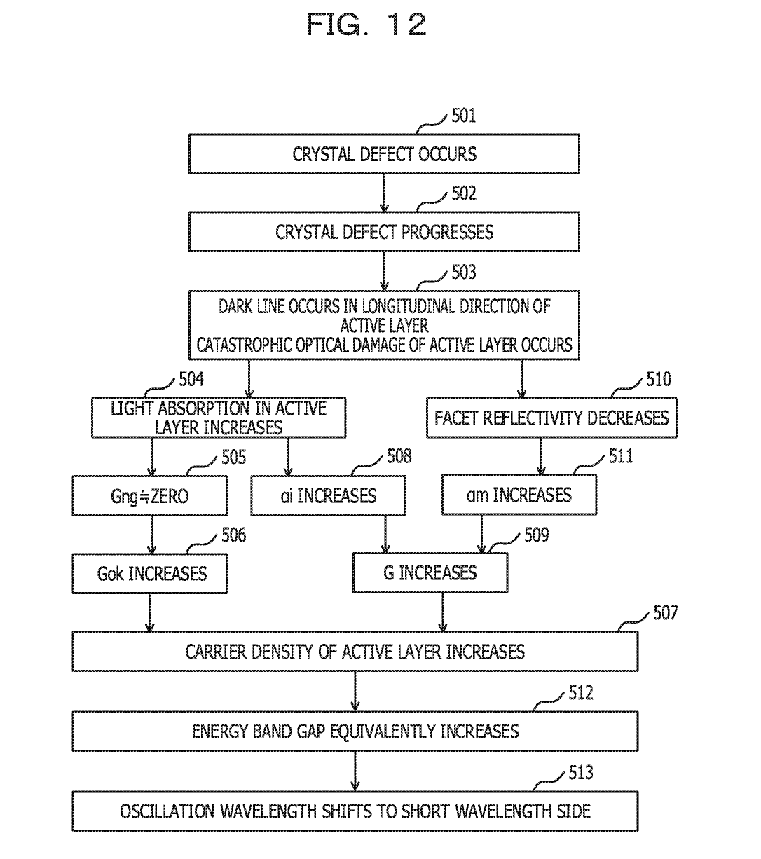

FIG. 12 illustrates an example of the causation between crystal defects and the wavelength shift. Reference numerals 501 to 513 indicated in FIG. 12 illustrate phenomena and the like in the active layer of the LD that contains aluminum or gallium arsenide in the active layer. A crystal defect first occurs due to various factors such as oxidation of an aluminum portion and stress (reference numeral 501). The crystal defect then progresses (increases and grows) due to various factors such as oxidation of the aluminum portion and stress (reference numeral 502). The current, temperature, and oxidation of aluminum in the active layer material, for example, serve as further accelerating factors of progress of the crystal defects (reference numeral 502).

The progress of the crystal defects (reference numeral 502) then results in a dark line (dark line defect (DLD)) in the longitudinal direction of the active layer and catastrophic optical damage (COD) of the active layer (reference numeral 503).

Occurrences of the dark line and the catastrophic optical damage (reference numeral 503) leads to an increase in light absorption in the active layer (reference numeral 504). The increase in light absorption in the active layer (reference numeral 504) makes the Gng gain of above equation (2) approach zero (reference numeral 505). Thus, in the relationship of above equation (2), the gain Gok relatively increases (reference numeral 506), and the carrier density of the active layer increases (reference numeral 507).

Further, the increase in light absorption in the active layer (reference numeral 504) leads to an increase in the internal loss αi of above equation (1) (reference numeral 508). Thus, in the relationship of above equation (1), the gain G relatively increases (reference numeral 509), and the carrier density of the active layer increases (reference numeral 507).

Further, the occurrences of the dark line and the catastrophic optical damage (reference numeral 503) lead to a decrease in a facet reflectivity (an increase in the mirror loss) (reference numeral 510). Further, the decrease in the facet reflectivity (reference numeral 510) leads to an increase in the resonant mirror loss am of above equation (1) (reference numeral 511). Thus, in the relationship of above equation (1), the gain G relatively increases (reference numeral 509), and the carrier density of the active layer increases (reference numeral 507).

As described above, the carrier density of the active layer increases due to a plurality of factors (reference numeral 507) as the crystal defects occur and progress. The increase in the carrier density of the active layer (reference numeral 507) leads to an equivalent increase in the energy band gap (reference numeral 512). The increase in the energy band gap (reference numeral 512) makes the oscillation wavelength shift toward the short wavelength side (reference numeral 513).

As illustrated in FIG. 12, in the LD, the carrier density of the active layer increases as the crystal defects in the active layer progresses, and the increase in the carrier density leads to an occurrence of the wavelength shift toward the short wavelength side. Further, for example, in a case where the active layer contains aluminum, oxidation of aluminum serves as the acceleration factor in the progress of the crystal defects. This is because an aluminum portion that is exposed on an end surface of the LD is likely to oxidize by a factor such as contact with air, for example, an aluminum oxide film is formed when the aluminum portion oxidizes, and a crystal structure in the active layer collapses.

However, the causation between the crystal defects and the wavelength shift is not limited to the semiconductor laser that contains aluminum in the active layer but applies to a VCSEL, for example, that contains gallium arsenide in the active layer and performs surface emission in a similar manner. That is, in the VCSEL that does not contain aluminum but contains gallium arsenide in the active layer, the carrier density of the active layer increases as the crystal defects progress, and the increase in the carrier density leads to an occurrence of the wavelength shift toward the short wavelength side.

(Causation Between Increase in Carrier Density of Active Layer and Wavelength Shift)

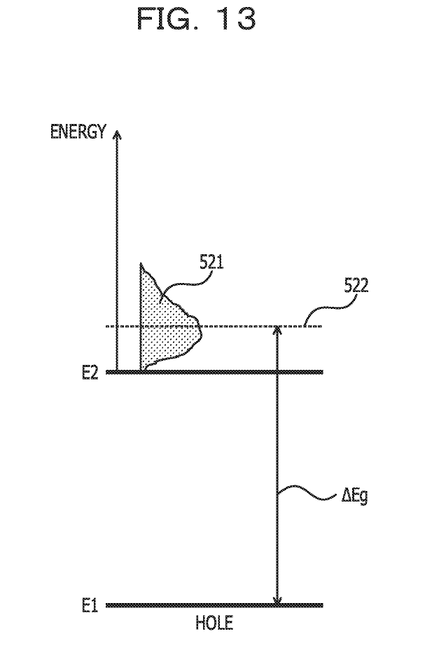

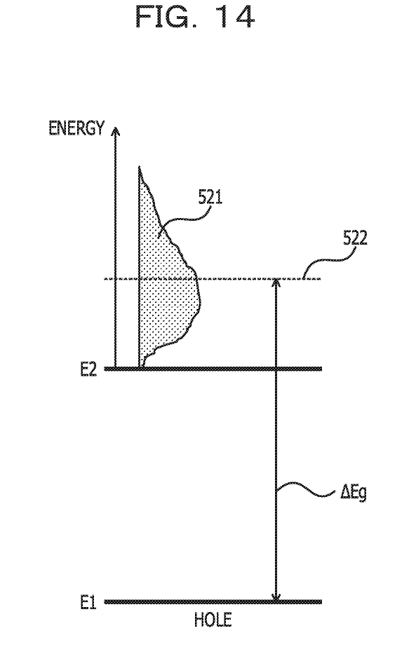

FIG. 13 is a diagram (part 1) that illustrates an example of the causation between the increase in the carrier density of the active layer and the wavelength shift. FIG. 14 is a diagram (part 2) that illustrates an example of the causation between the increase in the carrier density of the active layer and the wavelength shift. An electron distribution 521 in FIG. 13 represents an electron distribution in a normal LD. The electron distribution 521 in FIG. 14 represents an electron distribution in the LD that relatively shortly reaches the sudden failure. The electron distribution 521 has energy of an upper level E2 or higher.

A center of distribution 522 is an average value of energy of the electron distribution 521. The energy band gap ΔEg is the difference between a ground level E1 of the LD and the center of distribution 522. Further, the energy band gap ΔEg corresponds to the oscillation wavelength of the LD.

As described above, in the LD, the carrier density of the active layer increases due to the progress of defects in the active layer prior to the sudden failure. When the carrier density of the active layer increases, that is, the electron distribution 521 spreads to a higher energy range, the center of distribution 522 shifts toward a high energy side, and the energy band gap ΔEg becomes large. Thus, the oscillation wavelength of the LD shifts toward the short wavelength side.

(Dark Line Occurring in Active Layer of LD)

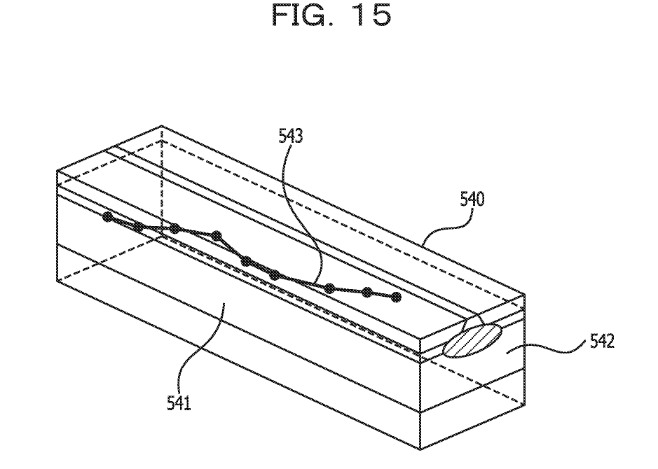

FIG. 15 illustrates an example of the dark line that occurs in the active layer of the LD. The judgment target of the judgment device 200 may be an LD chip 540 illustrated in FIG. 15, for example. The LD chip 540 is an LD chip that contains aluminum in an active layer 541.

In the LD chip 540, other than damage to an end surface 542, a dark line 543 occurs that is a non-light emission portion that gradually spreads due to oxidation of aluminum in the active layer 541. Expansion of the dark line 543 results in the shift of the oscillation wavelength of the LD chip 540 toward the short wavelength side.

However, as described above, even if the aluminum is not contained in the active layer, in a case where the active layer contains gallium arsenide (for example, the VCSEL), for example, the crystal structure collapses due to oxidation of the active layer or the like, the dark line occurs, and the crystal structure of the active layer collapses due to stress strain caused by the dark line. This leads to generation of a light absorption portion and further leads to the sudden failure and the wavelength shift toward the short wavelength side.

(Oscillation Wavelength Shift)

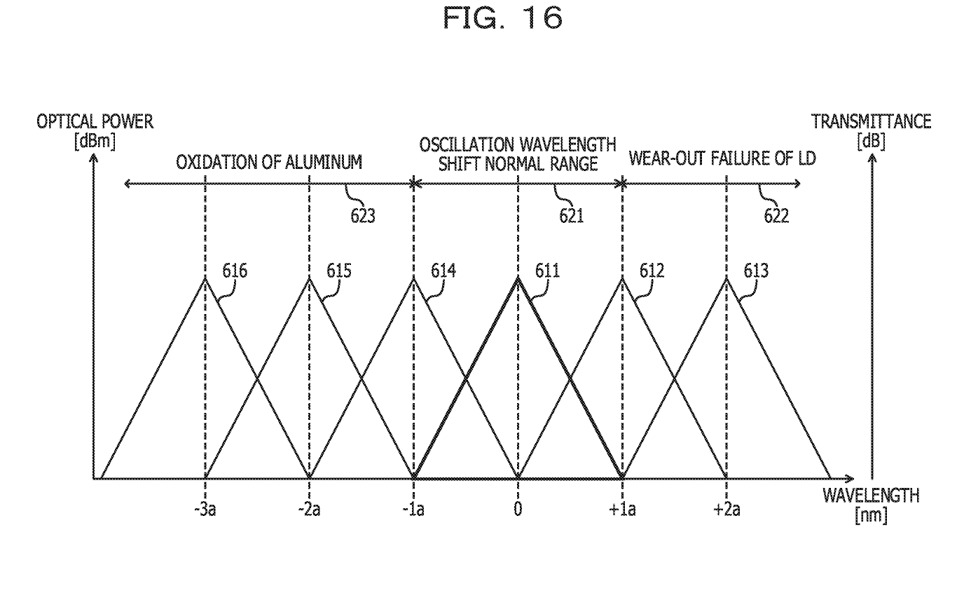

FIG. 16 illustrates an example of the oscillation wavelength shift. In FIG. 16, the horizontal axis represents the wavelength [nm], and the vertical axis represents optical power [dBm] and the transmittance [dB]. A spectrum 611 represents a spectrum in an initial state of oscillation light of the LD.

A wavelength range 621 represents a normal range of the oscillation wavelength of the LD (oscillation wavelength shift normal range) in consideration of the temperature, the drive current, the solid variation, and the like of the LD.

For example, a shift 622 of the oscillation wavelength of the LD toward a long wavelength side occurs due to a wear-out failure of the LD, and the oscillation light of the LD becomes like spectra 612 and 613. Further, a shift 623 of the oscillation wavelength of the LD toward the short wavelength side occurs due to oxidation of aluminum or the like in the active layer of the LD, and the oscillation light of the LD becomes like spectra 614 to 616.

(Relationship Between Oscillation Light in Initial State and Wavelength Transmission Characteristic of Optical Filter)

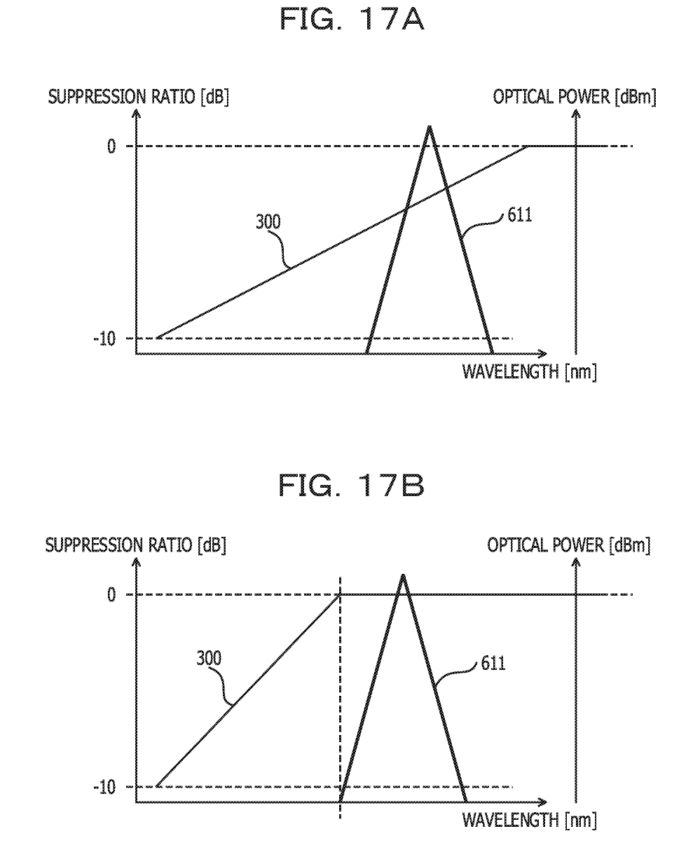

FIG. 17A illustrates an example of the relationship between the oscillation light in the initial state and the wavelength transmission characteristic of the optical filter. In FIG. 17A, the same reference numerals are provided to portions that are the same as the ones illustrated in FIG. 9A or FIG. 16, and a description thereof will not be made. As illustrated in FIG. 17A, the wavelength transmission characteristic 300 may be considered as a characteristic in which the spectrum 611 in the initial state of the oscillation light of the LD is contained in a band in which the transmittance continuously decreases toward the short wavelength side (for example, the wavelength band 311 illustrated in FIG. 9A), for example.

FIG. 17B illustrates another example of the relationship between the oscillation light in the initial state and the wavelength transmission characteristic of the optical filter. In FIG. 17B, the same reference numerals are provided to portions that are the same as the ones illustrated in FIG. 9A or FIG. 16, and a description thereof will not be made. As illustrated in FIG. 17B, the wavelength transmission characteristic 300 may be considered as a characteristic in which the spectrum 611 in the initial state of the oscillation light of the LD is rather contained in a band on the long wavelength side in which the transmittance is flat than a band in which the transmittance continuously decreases toward the short wavelength side, for example.

(Change in Transmittance in Wavelength Shift)

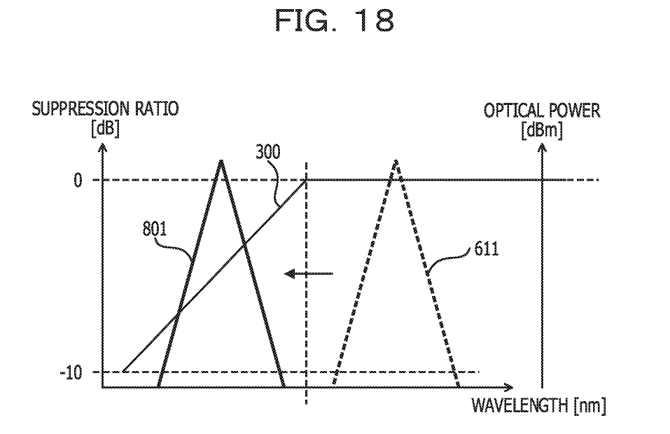

FIG. 18 illustrates an example of a change in the transmittance in the wavelength shift. In FIG. 18, the same reference numerals are provided to portions that are the same as the ones illustrated in FIGS. 17A and 17B, and a description thereof will not be made. Further, in FIG. 18, a description will be made about a case of a characteristic as illustrated in FIG. 17B in which the spectrum 611 in the initial state of the oscillation light of the LD is contained in a band in which the wavelength transmission characteristic 300 is flat. However, the change in the transmittance is similar in a case illustrated in FIG. 17A.

When the oscillation wavelength of the LD shifts toward the short wavelength side, the oscillation light of the LD becomes like spectrum 801. The transmittance of the oscillation light of the LD in the optical filter 202 thereby decreases. Thus, power of light that is output from the optical filter 202 is reduced, and a value that is stored in the time-series data storage section 205 may be changed.

(Decrease in Received Light Power of First PD Due to Wavelength Shift)

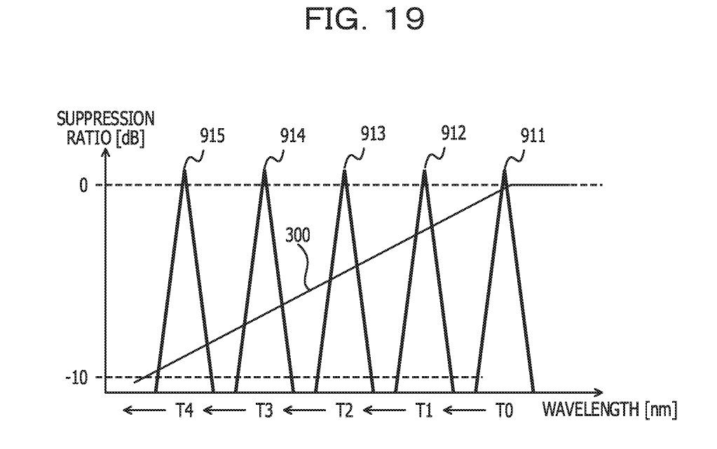

FIG. 19 illustrates an example of a decrease in the received light power of the first PD due to the wavelength shift. In FIG. 19, the same reference numerals are provided to portions that are the same as the ones illustrated in FIG. 9A, and a description thereof will not be made. In FIG. 19, the horizontal axis represents the wavelength [nm], and the vertical axis represents the suppression ratio [dB] (transmittance) of the optical filter 202.

Times T0 to T4 on the horizontal axis represents elapsed time from the time T0 as an initial point. Spectra 911 to 915 respectively represent spectra of the oscillation light of the LD at the times T0 to T4. As represented by the spectra 911 to 915, the suppression rate (transmittance) in the optical filter 202 gradually decreases as the oscillation wavelength of the LD shifts toward the short wavelength side in accordance with the elapsed time.

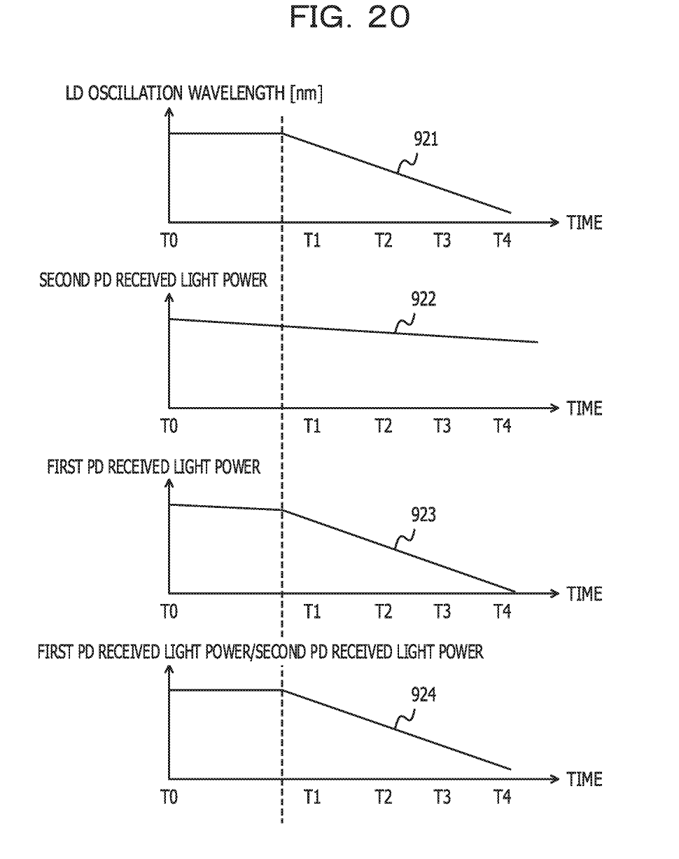

FIG. 20 illustrates an example of characteristics of portions with respect to the oscillation wavelength shift. In FIG. 20, the horizontal axis represents time. A graph 921 represents a change in the oscillation wavelength (LD oscillation wavelength) of the LD as the judgment target of the judgment device 200 in accordance with the elapsed time. A description will be made about a case as represented by the graph 921 where the shift of the oscillation wavelength of the LD toward the short wavelength side starts between the time T0 and the time T1 and the oscillation wavelength of the LD gradually shifts toward the short wavelength side in accordance with the elapsed time that is represented by the times T1 to T4.

A graph 922 represents a change in the received light power of the second PD 204 (second PD received light power) in accordance with the elapsed time. Light received by the second PD 204 reaches there not via the optical filter 202 and is thus not influenced by the shift of the oscillation wavelength of the LD as represented by the graph 922. However, as represented by the graph 922, the received light power of the second PD 204 may decrease due to fluctuations or the like of the temperature and the drive current of the LD.

A graph 923 represents a change in the received light power of the first PD 203 (first PD received light power) in accordance with the elapsed time. Light received by the first PD 203 reaches there via the optical filter 202 and thus decreases in accordance with the shift of the oscillation wavelength of the LD as represented by the graph 923.

A graph 924 represents a change in a ratio of the received light power of the first PD 203 to the received light power of the second PD 204 (first PD received light power/second PD received light power) in accordance with the elapsed time. The change is stored by the time-series data storage section 205. The received light power of the second PD 204 is not influenced by the shift of the oscillation wavelength of the LD toward the short wavelength side, but the received light power of the first PD 203 decreases.

Thus, as represented by the graph 924, the ratio of the received light power of the first PD 203 to the received light power of the second PD 204 does not change in a period in which the oscillation wavelength of the LD does not shift even if fluctuations or the like of the temperature and the drive current of the LD occur. Further, the ratio of the received light power of the first PD 203 to the received light power of the second PD 204 decreases when the oscillation wavelength of the LD shifts toward the short wavelength side. Accordingly, the ratio of the received light power of the first PD 203 to the received light power of the second PD 204 is used, thereby enabling the detection of the shift of the oscillation wavelength of the LD toward the short wavelength side.

(Dynamic Range of PD)

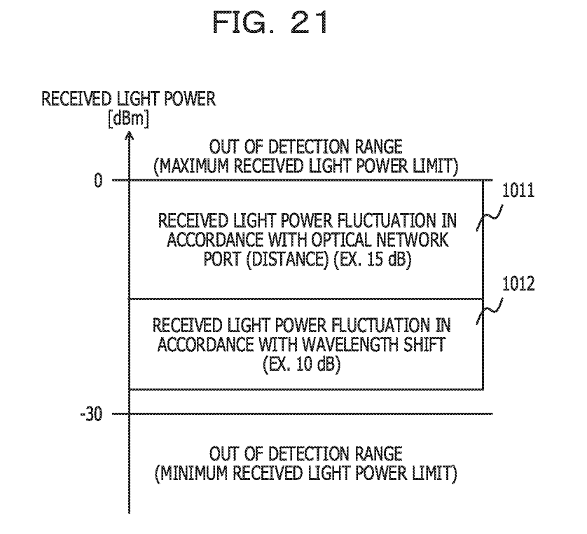

FIG. 21 illustrates an example of a dynamic range of the PD. In FIG. 21, the vertical axis represents the received light power [dBm] of the first PD 203 and the second PD 204. A dynamic range 1011 represents a dynamic range (for example, 15 dB) for a received light power fluctuation in accordance with an optical network port (distance), for example. A dynamic range 1012 represents a dynamic range (for example, 10 dB) for a received light power fluctuation in accordance with the wavelength shift.

A PD that has a dynamic range in which the dynamic range 1011 and the dynamic range 1012 are combined may be used for the first PD 203 and the second PD 204, for example. For example, a common PD of about 30 dB is used for the first PD 203 and the second PD 204, the dynamic ranges 1011 and 1012 may thereby be covered, and power of the LD including the fluctuation of the received light power in accordance with the wavelength shift may thus be monitored.

(Change in Oscillation Wavelength in Accordance with Elapsed Time)

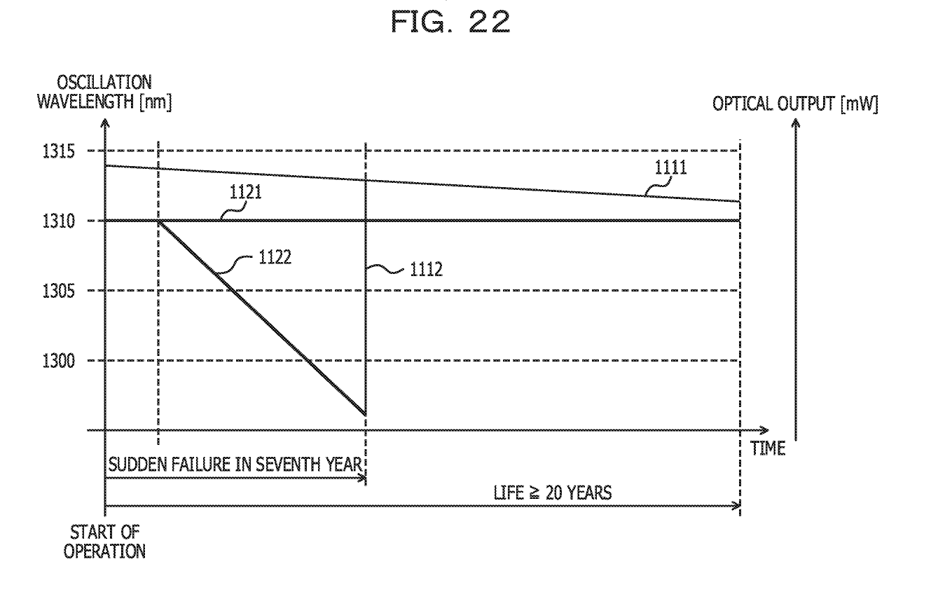

FIG. 22 is a diagram (part 1) that illustrates an example of a change in the oscillation wavelength in accordance with the elapsed time. In FIG. 22, the horizontal axis represents the elapsed time, and the vertical axis represents the oscillation wavelength [nm] of the LD and optical output [mW]. In FIG. 22, a description will be made about a case where the sudden failure occurs to the LD that contains aluminum or gallium arsenide in the active layer in the seventh year from a start of operation.

An optical output change 1111 represents a change in the optical output of the LD that does not contain aluminum or gallium arsenide in the active layer as a reference. As represented by the optical output change 1111, the optical output of the LD that does not contain aluminum or gallium arsenide in the active layer is not subjected to the sudden failure due to oxidation of aluminum or the like and gradually decreases in accordance with the elapsed time. In an example illustrated in FIG. 22, the life of the LD is 20 years or longer from the start of operation.

An optical output change 1112 represents a change in the optical output of the LD that contains aluminum or gallium arsenide in the active layer. As represented by the optical output change 1112, the optical output of the LD that contains aluminum or gallium arsenide in the active layer suddenly becomes zero in the seventh year from the start of operation, in the example illustrated in FIG. 22, due to the sudden failure caused by oxidation of aluminum or the like. Accordingly, it is difficult to predict the sudden failure of the LD by using the decrease in the optical output of the LD.

An oscillation wavelength change 1121 represents a change in the oscillation wavelength of the LD that does not contain aluminum or gallium arsenide in the active layer as a reference. As represented by the oscillation wavelength change 1121, the oscillation wavelength of the LD that does not contain aluminum or gallium arsenide in the active layer does not change in accordance with the elapsed time.

An oscillation wavelength change 1122 represents a change in the oscillation wavelength of the LD that contains aluminum or gallium arsenide in the active layer. As represented by the oscillation wavelength change 1122, the oscillation wavelength of the LD that contains aluminum or gallium arsenide in the active layer shifts toward the short wavelength side before the sudden failure of the LD (the seventh year in the example illustrated in FIG. 22). Accordingly, the shift of the oscillation wavelength of the LD toward the short wavelength side is monitored, thereby enabling the judgment about the sign of the sudden failure of the LD. Further, the shift of the oscillation wavelength of the LD toward the short wavelength side due to oxidation of aluminum or the like is a phenomenon unique to the LD to which the sudden failure occurs and may be monitored in an earlier stage than degradation of the optical output that is a sudden failure symptom.

(Change in Oscillation Wavelength in Accordance with Elapsed Time)

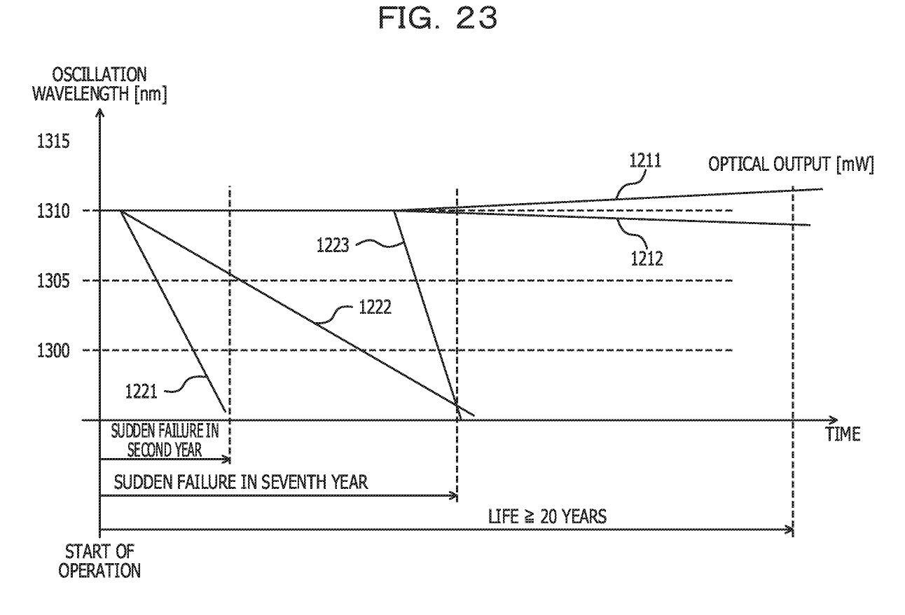

FIG. 23 is a diagram (part 2) that illustrates an example of the change in the oscillation wavelength in accordance with the elapsed time. In FIG. 23, the horizontal axis represents the elapsed time, and the vertical axis represents the oscillation wavelength [nm]. In FIG. 23, a description will be made about cases where the sudden failure occurs to the LD that contains aluminum or gallium arsenide in the active layer in the second year from the start of operation and where the sudden failure occurs to the LD that contains aluminum or gallium arsenide in the active layer in the seventh year from the start of operation.

An oscillation wavelength change 1211 represents a change in the oscillation wavelength of the LD that does not contain aluminum or gallium arsenide in the active layer as a reference. An oscillation wavelength change 1212 represents a change in the oscillation wavelength in an ideal case where the dark line (crystal defects) does not progress in the LD that contains aluminum or gallium arsenide in the active layer as a reference. The change in the oscillation wavelength of the LD in accordance with the elapsed time is small in cases represented by the oscillation wavelength changes 1211 and 1212. Further, the life of the LD is 20 years or longer from the start of operation.

An oscillation wavelength change 1221 represents a case where the aluminum portion or the like of the LD that contains aluminum or gallium arsenide in the active layer oxidizes, the dark line progresses fast, and the sudden failure occurs to the LD in the second year from the start of operation. An oscillation wavelength change 1222 represents a case where the aluminum portion or the like of the LD that contains aluminum or gallium arsenide in the active layer oxidizes, the dark line slowly progresses, and the sudden failure occurs to the LD in the seventh year from the start of operation. An oscillation wavelength change 1223 represents a case where the aluminum portion or the like of the LD that contains aluminum or gallium arsenide in the active layer oxidizes in a later stage, but the dark line progresses fast, and the sudden failure occurs to the LD in the seventh year from the start of operation.

For example, in a case where the dark line slowly progresses as an example represented by the oscillation wavelength change 1222, a judgment is made that the sign of the sudden failure is present in a case where the shift amount from an initial oscillation wavelength toward the short wavelength side is large, and a sufficient extension period may thereby be secured from the prediction of the sudden failure to the sudden failure.

On the other hand, in a case where the dark line progresses fast as examples represented by the oscillation wavelength changes 1221 and 1223, a sufficient extension period may not be secured from the prediction of the sudden failure to the sudden failure after the shift amount from the initial oscillation wavelength toward short wavelength side becomes large.

However, the judgment device 200 further makes a judgment that the sign of the sudden failure is present in a case where the wavelength shift amount for a short time is large and may thereby predict the sudden failure in an earlier stage in a case where the dark line progresses fast. Accordingly, a sufficient extension period may be secured from the prediction of the sudden failure to the sudden failure.

(Processing of Judgment Device)

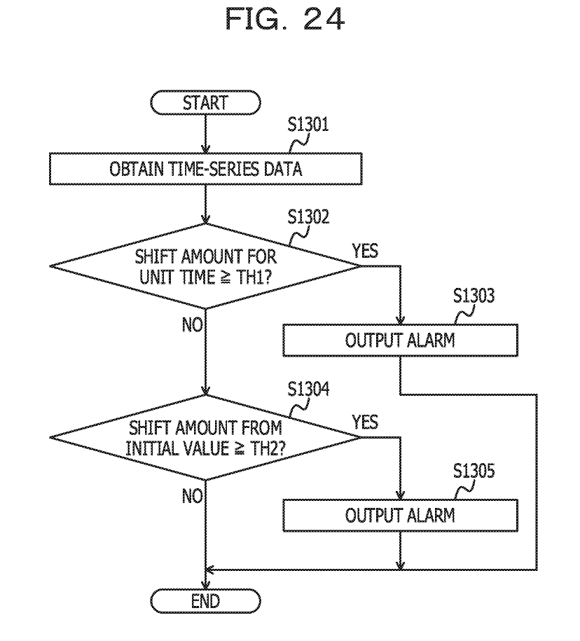

FIG. 24 is a flowchart that illustrates an example of processing of the judgment device. The short wave shift computation section 206 and the judgment section 207 of the judgment device 200 repeatedly execute steps illustrated in FIG. 24, for example. The short wave shift computation section 206 first obtains the time-series data that are stored in the time-series data storage section 205 (step S1301).

The short wave shift computation section 206 calculates a shift amount of the oscillation wavelength of the LD as the judgment target for a unit time based on the time-series data that are obtained in step S1301. The judgment section 207 then determines whether or not the shift amount that is calculated by the short wave shift computation section 206 is the prescribed value TH1 or greater (step S1302).

The shift amount that is calculated in step S1302 and so forth may not be the shift amount itself of the oscillation wavelength but may be an amount that corresponds to the shift amount of the oscillation wavelength. The amount that corresponds to the shift amount of the oscillation wavelength is the received light power of the first PD 203, the ratio of the received light power of the first PD 203 to the received light power of the second PD 204, or the like, for example.

In step S1302, in a case where the shift amount for the unit time is the prescribed amount TH1 or greater (step S1302: Yes), the judgment section 207 outputs an alarm that indicates that the sign of the sudden failure is present in the LD as the judgment target (step S1303), and a series of processes is finished.

In step S1302, in a case where the shift amount for the unit time is less than the prescribed value TH1 (step S1302: No), the short wave shift computation section 206 calculates the shift amount of the oscillation wavelength of the LD as the judgment target from an initial value based on the time-series data that are obtained in step S1301. The judgment section 207 then determines whether or not the shift amount of the oscillation wavelength of the LD as the judgment target from the initial value is the prescribed value TH2 or greater based on the shift amount that is calculated by the short wave shift computation section 206 (step S1304).

In step S1304, in a case where the shift amount from the initial value is the prescribed amount TH2 or greater (step S1304: Yes), the judgment section 207 outputs the alarm that indicates that the sign of the sudden failure is present in the LD as the judgment target (step S1305), and a series of processes is finished. In a case where the shift amount from the initial value is less than the prescribed amount TH2 (step S1304: No), the judgment device 200 finishes a series of processes.

Further, the prescribed value TH1 may be a value that is smaller than the prescribed value TH2. Accordingly, in a case where a rapid wavelength shift like the oscillation wavelength change 1222 illustrated in FIG. 23 occurs, for example, the alarm may be output in an early stage by step S1303.

(Communication System by Application of Judgment Device)

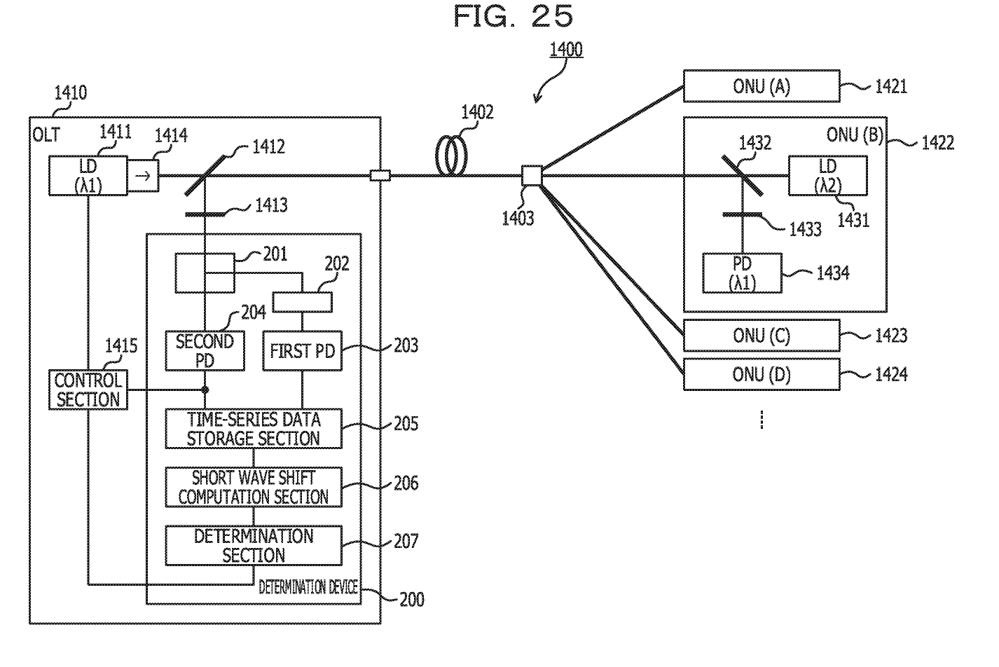

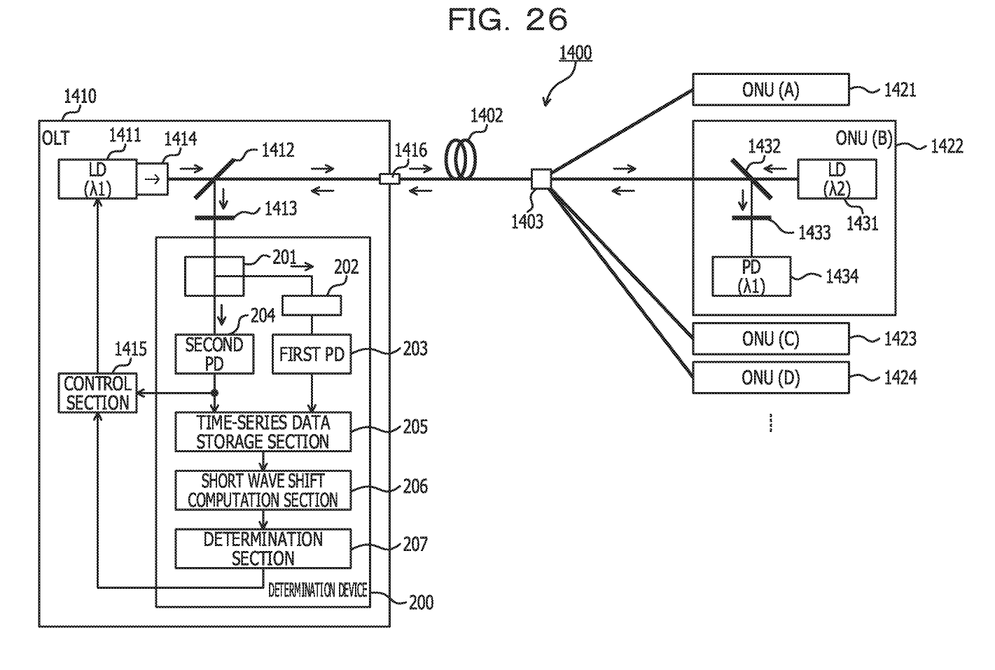

FIG. 25 illustrates an example of a communication system to which the judgment device is applied. FIG. 26 illustrates an example of flows of light and electricity in the communication system illustrated in FIG. 25. An optical communication system 1400 illustrated in FIGS. 25 and 26 is a PON system in which an optical line terminal (OLT) is connected with a plurality of optical network units (ONUs) by couplers.

In an example illustrated in FIGS. 25 and 26, the optical communication system 1400 includes an OLT 1410 and ONUs 1421 to 1424 (A to D), a channel 1402, and a splitter 1403. In the PON system like the optical communication system 1400, time slots are assigned to the ONUs 1421 to 1424 in a time division multiplexing manner, and the ONUs 1421 to 1424 transmit optical signals at defined timings. The judgment device 200 according to the second embodiment may be applied to the OLT 1410, for example.

The OLT 1410 includes an LD 1411, optical filters 1412 and 1413, the judgment device 200, an isolator 1414, and a control section 1415. The control section 1415 may be realized by digital circuits such as the DSP and the FPGA, for example.

The LD 1411 generates a downlink optical signal of a wavelength λ1 in accordance with control by the control section 1415 and emits the downlink optical signal to the optical filter 1412. The optical filter 1412 emits the downlink optical signal of the wavelength λ1 emitted from the LD 1411 from the OLT 1410 via a port 1416. Further, the optical filter 1412 emits light other than the wavelength λ1 of the light that is incident on the OLT 1410 via the port 1416 to the optical filter 1413.

The optical filter 1413 extracts an uplink light signal of a wavelength λ2, for example, of the light that is emitted from the optical filter 1412 and emits the uplink optical signal to the judgment device 200. The judgment device 200 makes the judgment of presence or absence of the sign of the sudden failure in the LD that generates the uplink optical signal (for example, an LD 1431 of the ONU 1422) based on the uplink optical signal of the wavelength λ2 that is emitted from the optical filter 1413. For example, the short wave shift computation section 206 of the judgment device 200 detects the shift amount toward a short wave side at timings based on the time division that corresponds to time slots assigned to subscribers.

The control section 1415 controls the LD 1411 and thereby performs a transmission process of the downlink optical signal. Further, the control section 1415 obtains a result of light reception by the second PD 204, for example, and thereby performs a reception process of the uplink optical signal. Further, for example, in a case where the alarm that indicates that the sign of the sudden failure of the LD 1431 of the ONU 1422 is present is output from the judgment device 200, the control section 1415 may control the LD 1411 and may thereby perform a process of transmitting switching instruction information of the active layers of the LD 1431 to the ONU 1422. Here, the control section 1415 may allow switching of the active layers of the LD 1431 in a rest period of the LD 1431 as a switching target.

The channel 1402 allows the downlink optical signal of the wavelength λ1 emitted from the OLT 1410 to pass through and emits that to a splitter 1403. The channel 1402 allows light emitted from the splitter 1403 to pass through and emits that to the OLT 1410.

The splitter 1403 splits light emitted from the channel 1402 into N beams (N=2, 3, 4, . . . ) and emits the N beams to N paths. Further, the splitter 1403 multiplexes beams emitted from the N paths and emits those to the channel 1402. For example, the respective beams from the N paths contain the uplink optical signals of the wavelength λ2 from the plurality of ONUs that include the ONUs 1421 to 1424.

A configuration of the ONU 1422 will next be described. Configurations of the ONUs 1421, 1423, and 1424 are the same. The ONU 1422 includes the LD 1431, optical filters 1432 and 1433, and a PD 1434. The LD 1431 generates the uplink optical signal of the wavelength λ2 and emits the uplink optical signal to the optical filter 1432. Further, the LD 1431 is an LD that contains aluminum or gallium arsenide in the active layer and is the judgment target of the judgment device 200.

The optical filter 1432 emits the uplink optical signal of the wavelength λ2 emitted from the LD 1431 from the ONU 1422. Further, the optical filter 1432 emits light other than the wavelength λ2 of the light that is incident on the ONU 1422 to the optical filter 1433.

The optical filter 1433 extracts the downlink light signal of the wavelength λ1 of the light that is emitted from the optical filter 1432 and emits the downlink optical signal to the PD 1434. The PD 1434 receives the downlink light signal of the wavelength λ1 that is emitted from the optical filter 1433 and outputs the received downlink optical signal.

The ONUs 1421 to 1424 transmit the uplink optical signals from the ONUs 1421 to 1424 in transmission periods that are notified from the OLT 1410, for example. Accordingly, the uplink optical signals from the ONUs 1421 to 1424 are transmitted in different periods from each other. Thus, the uplink optical signals from the ONUs 1421 to 1424 may be transmitted by optical time division multiplexing (OTDM).

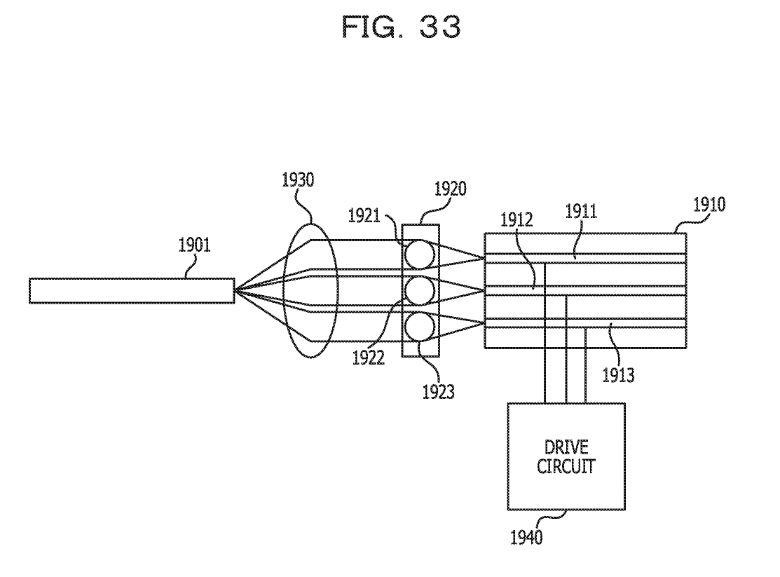

Further, each of the ONUs 1421 to 1424 may perform control to switch the LDs of the LD 1431 in a case where the switching instruction information is received from the OLT 1410 (for example, see FIGS. 33 to 40). Accordingly, the LDs of the LD 1431 are switched in a case where the judgment device 200 determines that the sign of the sudden failure of the LD 1431 is present, and the interruption of the transmission of the optical signals (system down) may thereby be avoided.

As described above, the judgment device 200 may be applied to the OLT 1410 of the optical communication system 1400, for example. In this case, the judgment targets of the judgment device 200 may be the LDs 1431 of the ONUs 1421 to 1424, for example. This enables autonomous recognition of the sign of the sudden failure of the individual LDs 1431 on a subscriber side by a single transmitting and receiving device (the OLT 1410) on a station side.

Further, the judgment target of the judgment device 200 may be the LD 1411 of the OLT 1410, for example. Further, the judgment device 200 may be applied to the ONU 1421 to 1424. In this case, the judgment targets of the judgment device 200 may be the LDs 1431 of the ONUs 1421 to 1424.

(Modification Examples of OLT)

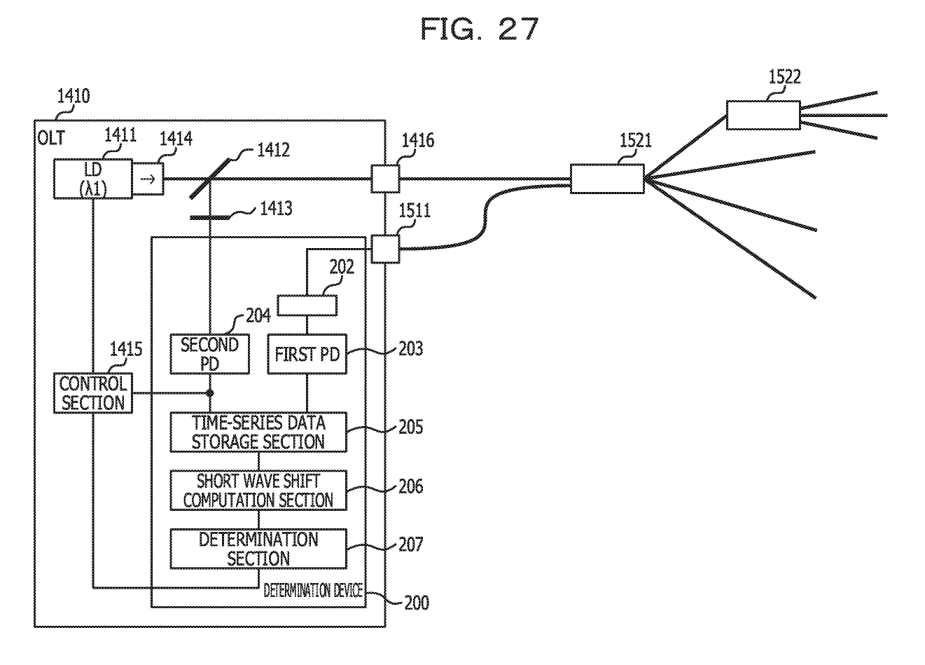

FIG. 27 illustrates a first modification example of the OLT. In FIG. 27, the same reference numerals are provided to portions that are the same as the ones illustrated in FIG. 25, and a description thereof will not be made. For example, it is assumed that the splitter 1403 illustrated in FIG. 25 is realized by splitting couplers 1521 and 1522 illustrated in FIG. 27.

The splitting coupler 1521 has a port that is connected with the port 1416 on the OLT 1410 and used for communication of the PON system and an unused port that is not connected with the port 1416 of the OLT 1410 and not used for communication of the PON system, on the OLT 1410 side.

The OLT 1410 includes a port 1511 that is connected with the unused port of the splitting coupler 1521 in addition to the port 1416. The OLT 1410 allows the uplink optical signal that is split and emitted by the splitting coupler 1521 to be incident from the ports 1416 and 1511.

The port 1511 emits the uplink optical signal that is incident from the splitting coupler 1521 to the optical filter 202. Accordingly, the uplink optical signal may be incident on the second PD 204 and the optical filter 202 without providing the optical branch unit 201 illustrated in FIGS. 25 and 26, for example. Size reduction of the device may thus be expected.

Further, a decrease in an intensity of the uplink optical signal that is incident on the second PD 204 and the optical filter 202 may be reduced, and light reception characteristics of the first PD 203 and the second PD 204 may be improved. Further, the optical filter 1413 may be omitted from a path of the uplink optical signal that is received by the first PD 203. This enables an improvement in judgment accuracy of the judgment device 200.

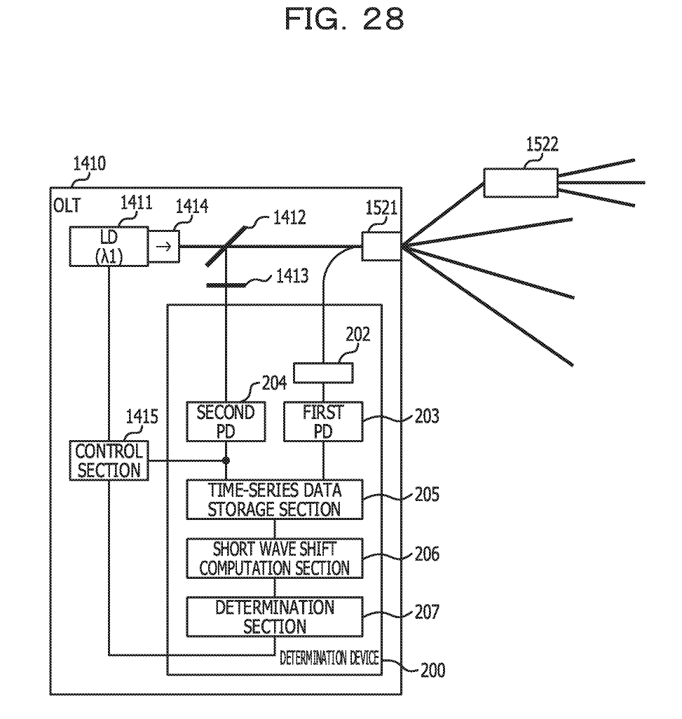

FIG. 28 illustrates a second modification example of the OLT. In FIG. 28, the same reference numerals are provided to portions that are the same as the ones illustrated in FIG. 27, and a description thereof will not be made. As illustrated in FIG. 28, a configuration is possible in which the splitting coupler 1521 illustrated in FIG. 27 is provided instead of the ports 1416 and 1511 of the OLT 1410.

As described above, the second embodiment enables the detection of the shift of the output wavelength toward the short wavelength side that appears as the sign of the sudden failure due to oxidation of aluminum or the like in an early stage in the LD 1431 or the like that contains aluminum or gallium arsenide in the active layer. This enables an early prediction of the sudden failure of the LD 1431 or the like. The prediction of the sudden failure of the LD 1431 or the like is enabled, and switching or the like of apparatuses prior to the sudden failure is thereby enabled, for example.

### Third Embodiment

### Optical Amplifier According to Third Embodiment

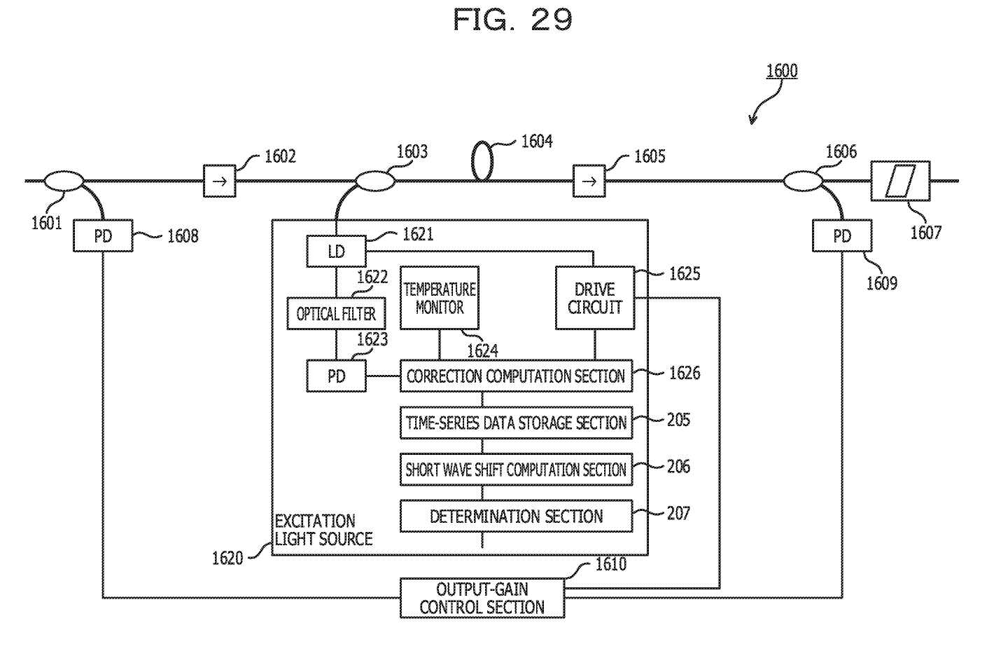

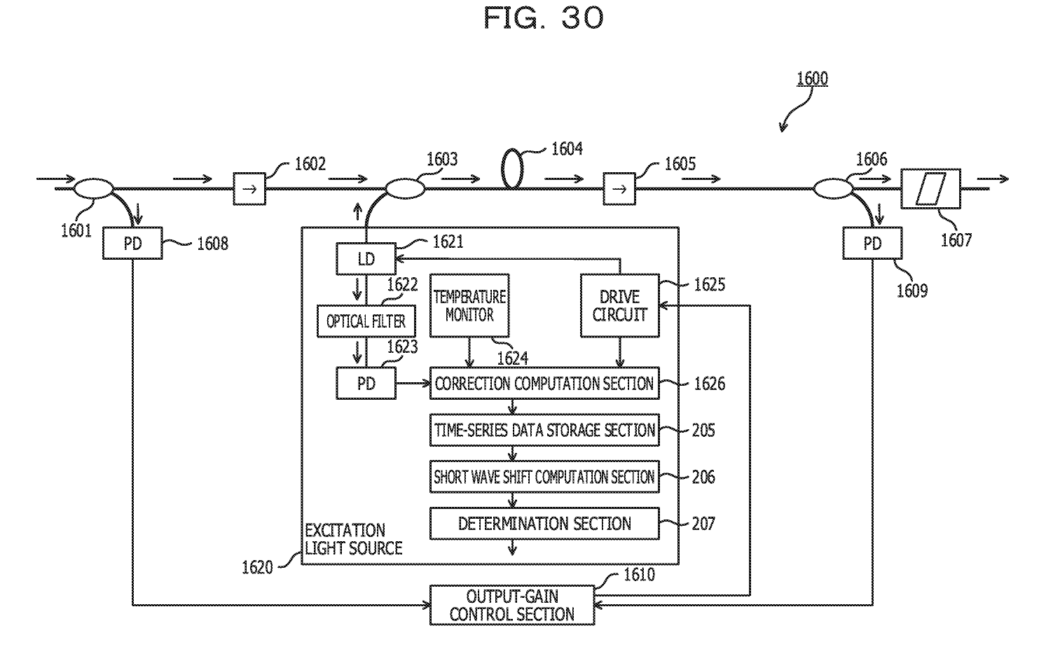

FIG. 29 illustrates an example of an optical amplifier according to the third embodiment. FIG. 30 illustrates an example of flows of light and electricity in the optical amplifier illustrated in FIG. 29. In FIGS. 29 and 30, the same reference numerals are provided to portions that are the same as the ones illustrated in FIGS. 7A to 8B, and a description thereof will not be made. An optical amplifier 1600 illustrated in FIGS. 29 and 30 is an erbium-doped fiber amplifier (EDFA) that uses the EDF.

As illustrated in FIGS. 29 and 30, the optical amplifier 1600 according to the third embodiment includes an optical branch unit 1601, an isolator 1602, a multiplexing unit 1603, an EDF 1604, an isolator 1605, an optical branch unit 1606, and an optical filter 1607. Further, the optical amplifier 1600 includes PDs 1608 and 1609, an output-gain control section 1610, and an excitation light source 1620.

The optical branch unit 1601 splits signal light that is incident on the optical amplifier 1600 and emits beams of the split signal light to the isolator 1602 and the PD 1608. The isolator 1602 emits the signal light that is emitted from the optical branch unit 1601 to the multiplexing unit 1603. Further, the isolator 1602 blocks light that is emitted from the multiplexing unit 1603.

The multiplexing unit 1603 multiplexes the signal light emitted from the isolator 1602 with excitation light emitted from the excitation light source 1620. The multiplexing unit 1603 then emits the multiplexed light to the EDF 1604. The EDF 1604 allows the light emitted from the multiplexing unit 1603 to pass through and emits that to the isolator 1605. Further, the EDF 1604 is an optical gain medium that amplifies the signal light contained in the light that passes through in accordance with the excitation light contained in the light that passes through.

The isolator 1605 emits the light that is emitted from the EDF 1604 to the optical branch unit 1606. Further, the isolator 1605 blocks light that is emitted from the optical branch unit 1606. The optical branch unit 1606 splits the light that is emitted from the isolator 1605. The optical branch unit 1606 then emits beams of the split light to the optical filter 1607 and the PD 1609.

The optical filter 1607 transmits only a signal wavelength component of the light that is emitted from the optical branch unit 1606 and thereby extracts and emits the signal light that is contained in the light emitted from the optical branch unit 1606.

The PD 1608 receives the signal light that is emitted from the optical branch unit 1601. The PD 1608 then outputs an electric signal that indicates the power of the received signal light to the output-gain control section 1610. The PD 1609 receives the light that is emitted from the optical branch unit 1606. The PD 1609 then outputs an electric signal that indicates the power of the received signal light to the output-gain control section 1610.

The output-gain control section 1610 controls a drive circuit 1625 of the excitation light source 1620 and thereby controls the power of the excitation light that is emitted from the excitation light source 1620. For example, the output-gain control section 1610 performs auto power control (APC) in which emission light power of the excitation light source 1620 is controlled based on the electric signal output from the PD 1609 and output power of the optical amplifier 1600 is controlled to be maintained at a certain magnitude.

Alternatively, the output-gain control section 1610 performs automatic gain control (AGC) in which the emission light power of the excitation light source 1620 is controlled based on the ratio between the electric signals that are output from the PDs 1608 and 1609 and a gain of the optical amplifier 1600 is controlled to be maintained at a certain magnitude.

The excitation light source 1620 emits the excitation light to the multiplexing unit 1603. The excitation light source 1620 includes an LD 1621, an optical filter 1622, a PD 1623, a temperature monitor 1624, the drive circuit 1625, a correction computation section 1626, the time-series data storage section 205, the short wave shift computation section 206, and the judgment section 207.

The LD 1621 oscillates light that corresponds to a drive current supplied from the drive circuit 1625 and emits the oscillation light to the multiplexing unit 1603 as the excitation light. Further, the LD 1621 emits backward light to the optical filter 1622. Further, the LD 1621 is a semiconductor laser for excitation that contains aluminum or gallium arsenide in the active layer.

The optical filter 1622 transmits the light that is emitted from the LD 1621 by a characteristic of transmitting prescribed wavelengths and emits the transmitted light to the PD 1623. A wavelength transmission characteristic of the optical filter 1622 is a similar wavelength transmission characteristic (for example, see FIG. 9A) to the optical filter 202 illustrated in FIGS. 7A and 7B, for example. The PD 1623 receives the light that is emitted from the optical filter 1622 and outputs an electric signal that indicates the power of the received light to the correction computation section 1626.

The temperature monitor 1624 performs real-time monitoring of the temperature of the LD 1621. The temperature monitor 1624 then notifies the correction computation section 1626 of the temperature that is obtained in the monitoring. The drive circuit 1625 drives the LD 1621 by supplying the drive current to the LD 1621. Further, the drive circuit 1625 adjusts the drive current to be supplied to the LD 1621 in accordance with the control by the output-gain control section 1610. Further, the drive circuit 1625 performs real-time monitoring of the magnitude of the drive current that is supplied to the LD 1621 and notifies the correction computation section 1626 of a monitoring result.

The correction computation section 1626 corrects the electric signal that is output from the PD 1623 in accordance with the temperature notified from the temperature monitor 1624 and the drive current notified from the drive circuit 1625. For example, the correction computation section 1626 performs correction by using a database of the correlation between the drive current and the temperature of the LD 1621 and the oscillation wavelength.

This enables obtainment of an electric signal that indicates the shift amount of the oscillation wavelength of the LD 1621, from which differences due to fluctuations of the temperature and the drive current of the LD 1621 are removed. The correction computation section 1626 outputs the corrected electric signal to the time-series data storage section 205.

The time-series data storage section 205 stores time-series data of the corrected electric signal that is output from the correction computation section 1626. Accordingly, the judgment of presence or absence of the sign of the sudden failure in the LD 1621 may be made by the judgment section 207. Further, the electric signal is corrected by the correction computation section 1626, and the judgment of presence or absence of the sign of the sudden failure in the LD 1621 may thereby be made with high accuracy even if the temperature or the drive current of the LD 1621 fluctuates.

Further, for example, the excitation light source 1620 may be provided with a control section that controls the LD 1621 and performs control to switch LDs of the LD 1621 in a case where the alarm that indicates that the sign of the sudden failure of the LD 1621 is present is output from the judgment section 207. The control section, the correction computation section 1626, and the output-gain control section 1610 may be realized by digital circuits such as the DSP and the FPGA, for example.

Further, a cycle of a judgment process about the sign of the sudden failure of the LD 1621 in the excitation light source 1620 may be set shorter than a control cycle of the drive current of the LD 1621 by the output-gain control section 1610 (for example, 1/10 or shorter). Accordingly, the judgment of presence or absence of the sign of the sudden failure in the LD 1621 may be made with high accuracy even if there are a change in the drive current and a LD temperature change due to the control of the output-gain control section 1610.

In FIGS. 29 and 30, a description is made about a forward pumping configuration in which the excitation light from the excitation light source 1620 is incident from a front stage of the EDF 1604. However, a backward pumping configuration is possible in which the excitation light from the excitation light source 1620 is incident from a rear stage of the EDF 1604. Further, a bi-directional pumping configuration is possible in which two excitation light sources 1620 are provided and the excitation light from the excitation light sources 1620 is incident from the front stage and the rear stage.

The judgment device 200 illustrated in FIGS. 7A to 8B may be applied to the excitation light source 1620 illustrated in FIGS. 29 and 30, for example. In this case, a configuration is possible from which the temperature monitor 1624 and the correction computation section 1626 are omitted, for example. Further, a configuration is applicable in which forward optical output power of the LD is split and monitored as illustrated in FIGS. 1A, 1B, 3A, 3B, 5A, and 5B, for example.

(Characteristics of Oscillation Wavelengths in Accordance with Temperature with Respect to Drive Current)

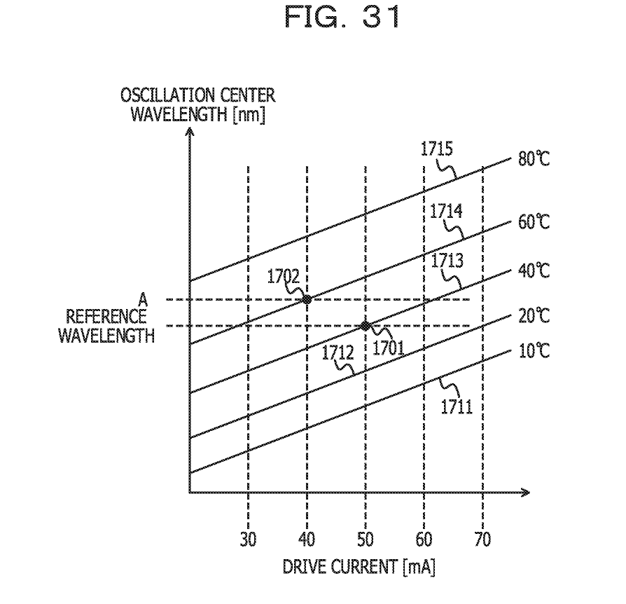

FIG. 31 illustrates an example of characteristics of the oscillation wavelengths in accordance with the temperature with respect to the drive current. In FIG. 31, the horizontal axis represents the drive current [mA] that is supplied to the LD 1621, and the vertical axis represents oscillation center wavelength [nm] of the LD 1621.

LD characteristics 1711 to 1715 represent characteristics of the oscillation center wavelengths of the LD 1621 with respect to the drive current that is supplied to the LD 1621 in cases of temperatures of 10° C., 20° C., 40° C., 60° C., and 80° C., respectively. A database that indicates the LD characteristics 1711 to 1715 is stored in a memory of the optical amplifier 1600, for example.

The correction computation section 1626 corrects the electric signal output from the PD 1623 to an electric signal in a case where the temperature of the LD 1621 is a reference temperature and the drive current of the LD 1621 is a reference drive current based on the database stored in the memory.

For example, as represented by a reference point 1701, it is assumed that the reference temperature of the LD 1621 is 40° C., the drive current of the LD 1621 is 50 mA, and an initial wavelength of the LD 1621 is a prescribed reference wavelength. Further, as represented by a measurement point 1702, it is assumed that the temperature notified from the temperature monitor 1624 is 60° C. and the drive current notified from the drive circuit 1625 is 40 mA.

In this case, the correction computation section 1626 derives an oscillation center wavelength A at the temperature (60° C.) notified from the temperature monitor 1624 and the drive current (40 mA) notified from the drive circuit 1625 based on the database. The correction computation section 1626 calculates the difference between the oscillation center wavelength A and the reference wavelength (A−reference wavelength).

Further, the correction computation section 1626 multiplies a received light power P1 that is indicated by the electric signal output from the PD 1623 by a slope [dB/nm] of the wavelength transmission characteristic of the optical filter 1622 to calculate the wavelength λ1 of the LD 1621 that is not yet corrected. The correction computation section 1626 then calculates λ1−(A−reference wavelength) by the calculated wavelength λ1 and (A−reference wavelength) and may thereby obtain a corrected wavelength.

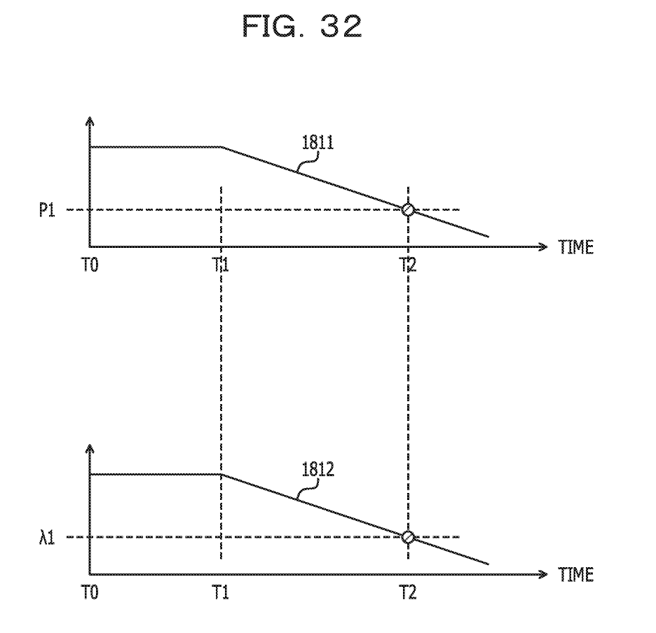

FIG. 32 illustrates an example of the relationship between the change in the PD received light power in accordance with the elapsed time and the oscillation wavelength. In FIG. 32, the horizontal axis represents the time. A graph 1811 illustrated in FIG. 32 represents a change in the received light power of the PD 1623 in accordance with the elapsed time. For example, it is assumed that the oscillation wavelength of the LD 1621 shifts toward the short wavelength side from a time T1 to a time T2 and the received light power of the PD 1623 decreases. A graph 1812 illustrated in FIG. 32 represents a change in the oscillation wavelength of the LD 1621 in accordance with the elapsed time.

For example, because the received light power of the PD 1623 is P1 at the time T2, the wavelength λ1 of the LD 1621 at the time T2 may be calculated by λ1=P1×α. A term α is a slope [dB/nm] of the suppression ratio (transmittance) to the wavelength in the optical filter 1622.

The correction computation section 1626 corrects the calculated λ1 to the oscillation wavelength at the reference temperature (40° C.) and the reference drive current (50 mA). For example, the correction computation section 1626 calculates λ1−(A−reference wavelength) and may thereby obtain the wavelength that is corrected to the oscillation wavelength at the reference temperature (40° C.) and the reference drive current (50 mA).

As described above, the third embodiment enables the detection of the shift of the output wavelength toward the short wavelength side that appears as the sign of the sudden failure due to oxidation of aluminum in an early stage in the LD 1621 or the like that contains aluminum or gallium arsenide in the active layer. This enables an early prediction of the sudden failure of the LD 1621 or the like. The early prediction of the sudden failure of the LD 1621 or the like is enabled, and switching or the like of apparatuses prior to the sudden failure is thereby enabled, for example.

(LD Chip Capable of Switching LDs)

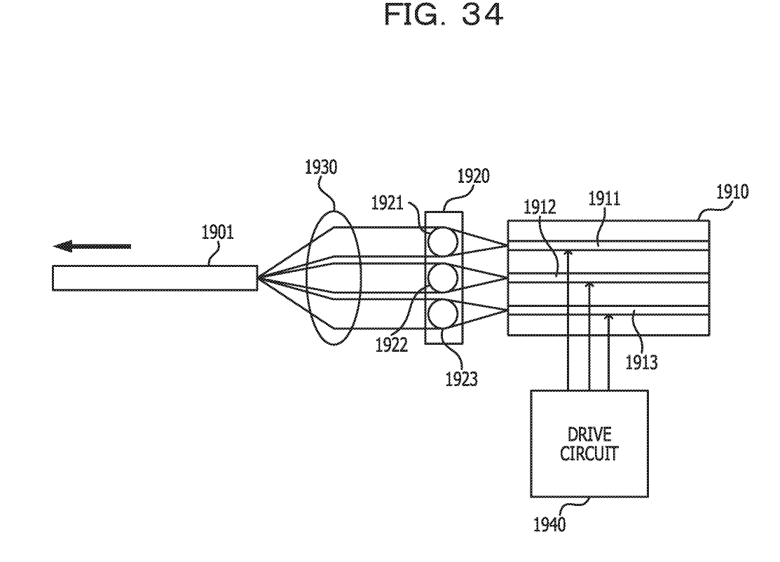

FIG. 33 illustrates an example of an LD chip that is capable of switching LDs. FIG. 34 illustrates an example of flows of light and electricity in a configuration of the LD chip illustrated in FIG. 33. In FIGS. 33 and 34, the same reference numerals are provided to portions that are the same as the ones illustrated in FIGS. 7A and 7B, and a description thereof will not be made.

For example, an LD chip 1910 illustrated in FIGS. 33 and 34 may be used for the LD 1431 illustrated in FIGS. 25 and 26 and the LD 1621 illustrated in FIGS. 29 and 30. The LD chip 1910 is an LD chip that contains three active layers, for example. Signal electrodes 1911 to 1913 are anode (or cathode) electrodes that correspond to the three active layers of the LD chip 1910.

A drive circuit 1940 inputs the drive current to any of the signal electrodes 1911 to 1913, for example, and makes any of the active layers of the LD chip 1910 emit light. In this case, as illustrated in FIGS. 33 and 34, a lens array 1920 and a condenser lens 1930 may be provided between the LD chip 1910 and an optical fiber 1901.

The lens array 1920 has microlenses 1921 to 1923. The microlenses 1921 to 1923 are provided for the respective three active layers of the LD chip 1910, collimate beams of light emitted from the respective active layers, and emit the beams to the condenser lens 1930. The condenser lens 1930 condenses the beams of light emitted from the microlenses 1921 to 1923 to the optical fiber 1901.

Alternatively, instead of the lens array 1920 and the condenser lens 1930, the beams of light may be condensed to the optical fiber 1901 by using an aspheric lens or the like in which a lens aberration is reduced in positions through which the beams of light emitted from the three active layers of the LD chip 1910 pass.

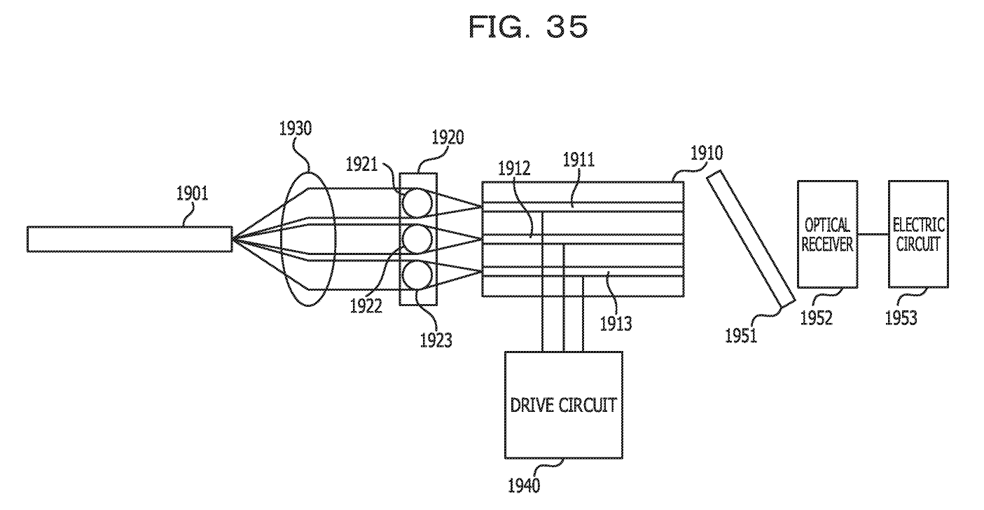

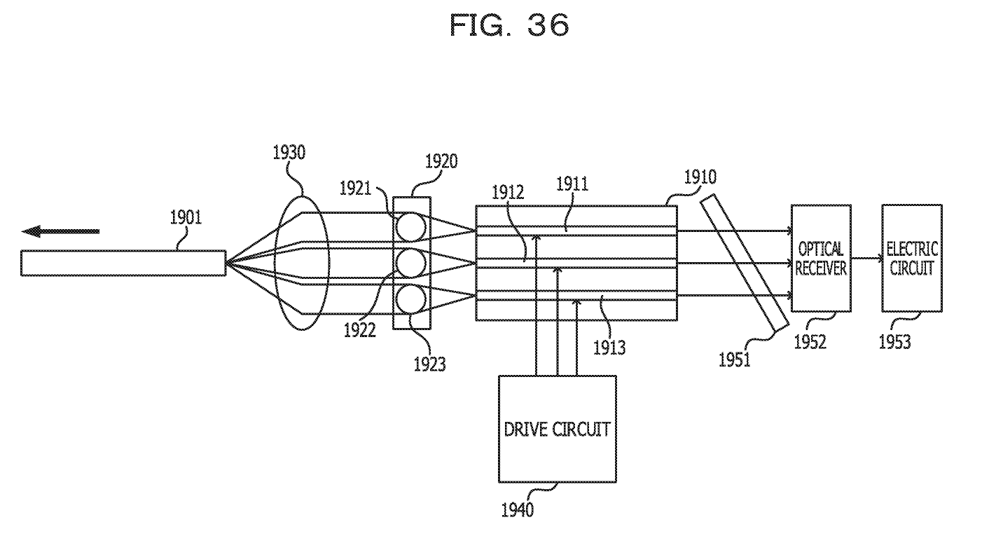

FIG. 35 illustrates a modification example of the LD chip illustrated in FIG. 33. FIG. 36 illustrates an example of flows of light and electricity in a configuration of the LD chip illustrated in FIG. 35. In FIGS. 35 and 36, the same reference numerals are provided to portions that are the same as the ones illustrated in FIGS. 33 and 34, and a description thereof will not be made. As illustrated in FIGS. 35 and 36, the LD chip 1910 may include an optical filter 1951, an optical receiver 1952, and an electric circuit 1953 in addition to the configuration illustrated in FIGS. 33 and 34.

The optical filter 1951 has a characteristic of transmitting prescribed wavelengths and transmits backward light of the LD chip 1910. The optical filter 1951 has a configuration that corresponds to the above-described optical filter 202 or the optical filter 1622, for example. The optical receiver 1952 receives light transmitted through the optical filter 1951. The optical receiver 1952 has a configuration that corresponds to the above-described first PD 203 or the PD 1623, for example.

The electric circuit 1953 processes an electric signal of a result of light reception by the optical receiver 1952. The electric circuit 1953 has a configuration that corresponds to the time-series data storage section 205, the short wave shift computation section 206, and the judgment section 207 or the correction computation section 1626. Further, a control circuit may be provided that outputs the switching instruction information to the drive circuit 1940 based on a judgment result of the sudden failure by the electric circuit 1953.

A description is made here about a configuration in which the backward light of the LD chip 1910 is monitored. However, a configuration is possible in which forward light of the LD chip 1910 is split and monitored by the optical filter 1951, the optical receiver 1952, and the electric circuit 1953.

(Drive Circuit and LD Chip)

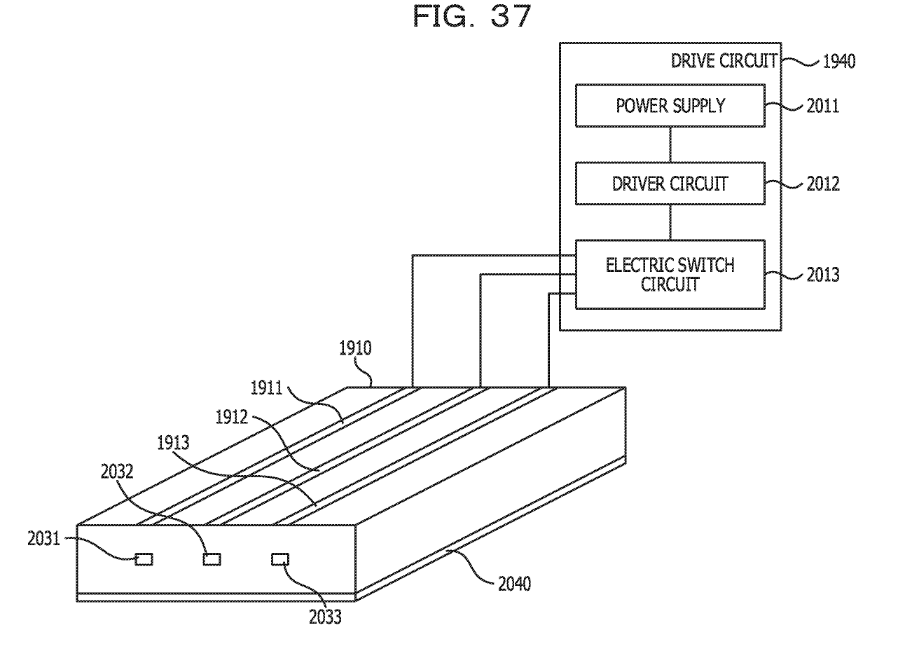

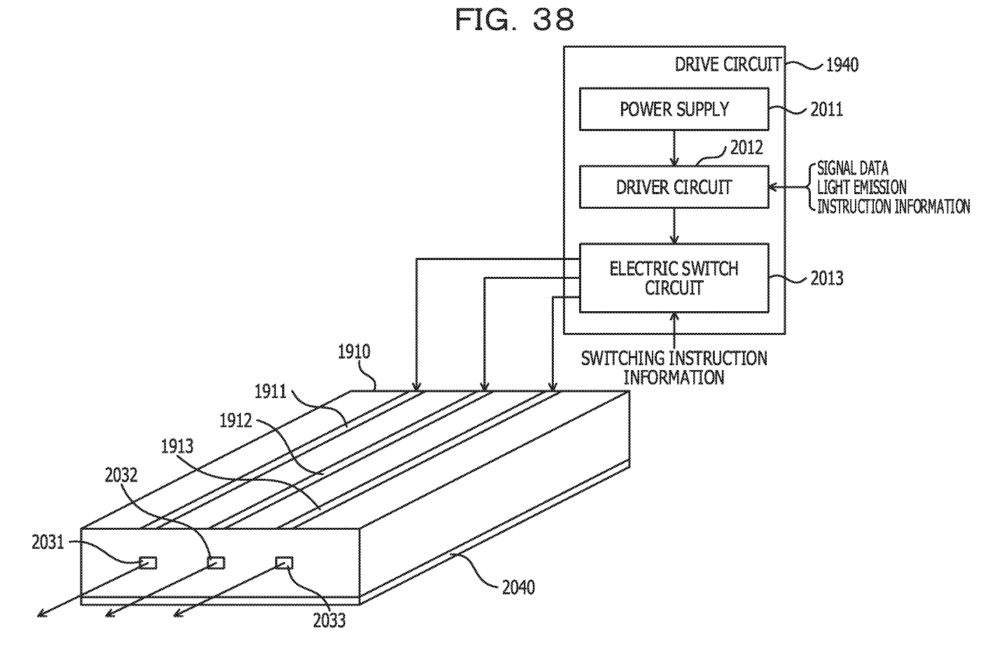

FIG. 37 illustrates an example of the drive circuit and the LD chip. FIG. 3B illustrates an example of flows of light and electricity in the drive circuit and the LD chip illustrated in FIG. 37. In FIGS. 37 and 38, the same reference numerals are provided to portions that are the same as the ones illustrated in FIGS. 33 and 34, and a description thereof will not be made.

As illustrated in FIGS. 37 and 38, the drive circuit 1940 includes a power supply 2011, a driver circuit 2012, and an electric switch circuit 2013, for example. The power supply 2011 supplies a power source to generate the drive current. The driver circuit 2012 uses the power source supplied by the power supply 2011 to generate the drive current that corresponds to signal data or light emission instruction information that are input to the driver circuit 2012. The driver circuit 2012 then outputs the generated drive current to the electric switch circuit 2013.

The electric switch circuit 2013 applies the drive current that is output from the driver circuit 2012 to any of the signal electrodes 1911 to 1913 of the LD chip 1910. Further, when the switching instruction information is input, the electric switch circuit 2013 switches the signal electrodes to which the drive current is applied among the signal electrodes 1911 to 1913.

The LD chip 1910 has the signal electrodes 1911 to 1913, active layers 2031 to 2033, and a grounding electrode 2040. The signal electrodes 1911 to 1913 are provided on one surface of the LD chip 1910. The drive current from the drive circuit 1940 is applied to the signal electrodes 1911 to 1913. The grounding electrode 2040 is provided on a surface of the LD chip 1910 on the opposite side to the surface on which the signal electrodes 1911 to 1913 are provided.

The active layers 2031 to 2033 are provided between the respective signal electrodes 1911 to 1913 and the grounding electrode 2040. The active layers 2031 to 2033 individually emit light in accordance with the drive current applied to the respective signal electrodes 1911 to 1913. Beams of light that are emitted from the active layers 2031 to 2033 are incident on the lens array 1920 illustrated in FIGS. 33 and 34, for example. As described above, in the LD chip 1910 illustrated in FIGS. 37 and 38, three LDs are formed with the signal electrodes 1911 to 1913, the active layers 2031 to 2033, and the grounding electrode 2040.

(Electric Switch Circuit)

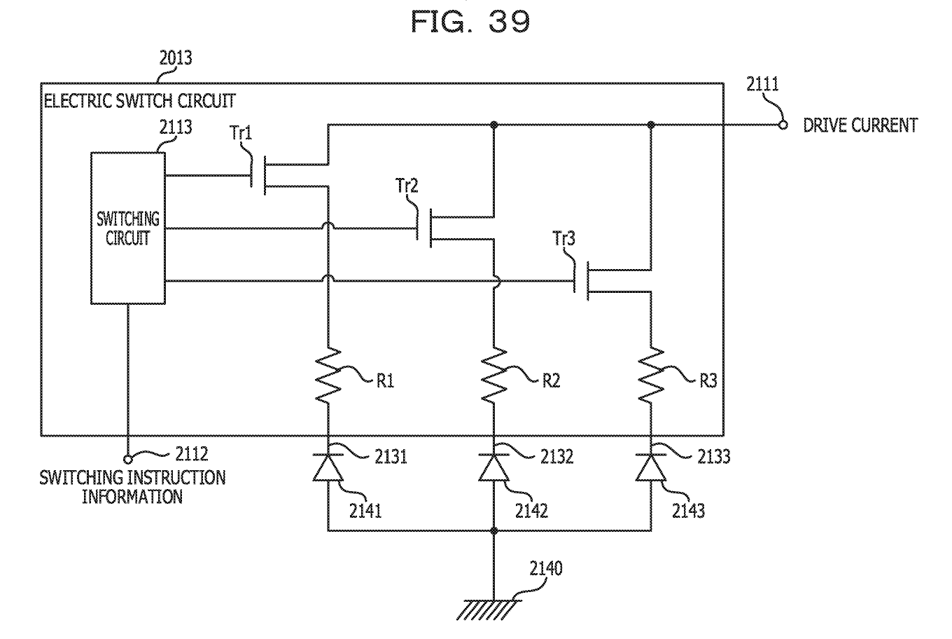

FIG. 39 illustrates an example of the electric switch circuit. As illustrated in FIG. 39, the electric switch circuit 2013 illustrated in FIGS. 37 and 38 includes input terminals 2111 and 2112, a switching circuit 2113, transistors Tr1 to Tr3, and resistors R1 to R3, for example.

The drive current that is output from the driver circuit 2012 (for example, see FIGS. 37 and 38) is input to the input terminal 2111. The switching instruction information that is transmitted in accordance with the alarm from the judgment section 207 is input to the input terminal 2112.

The transistors Tr1 to Tr3 may be realized by field effect transistors (FETs), for example. In the transistor Tr1, a gate is connected with the switching circuit 2113, a drain is connected with the input terminal 2111, and a source is connected with the resistor R1. In the transistor Tr2, a gate is connected with the switching circuit 2113, a drain is connected with the input terminal 2111, and a source is connected with the resistor R2. In the transistor Tr3, a gate is connected with the switching circuit 2113, a drain is connected with the input terminal 2111, and a source is connected with the resistor R3.

In the resistor R1, one end is connected with the transistor Tr1, and the other end is connected with an electrode 2131. In the resistor R2, one end is connected with the transistor Tr2, and the other end is connected with an electrode 2132. In the resistor R3, one end is connected with the transistor Tr3, and the other end is connected with an electrode 2133.

The electrodes 2131 to 2133 illustrated in FIG. 39 correspond to the signal electrodes 1911 to 1913, respectively, which are illustrated in FIGS. 37, 38, and so forth. LDs 2141 to 2143 correspond to the active layers 2031 to 2033, respectively, which are illustrated in FIGS. 37 and 38. A ground 2140 corresponds to the grounding electrode 2040 illustrated in FIGS. 37 and 38.

The switching circuit 2113 switches voltages that are applied to the gates of the transistors Tr1 to Tr3 in accordance with the switching instruction information that is input from the input terminal 2112. An operation of the switching circuit 2113 will next be described.

(Operation of Switching Circuit of Electric Switch Circuit)

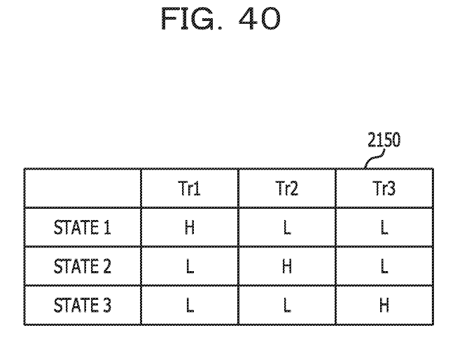

FIG. 40 illustrates an example of the operation of the switching circuit of the electric switch circuit. The switching circuit 2113 of the electric switch circuit 2013 illustrated in FIG. 39 operates in accordance with a state table 2150 illustrated in FIG. 40, for example.

In the state table 2150, “state 1”, “state 2”, and “state 3” correspond to the voltages that are applied to the gates of the transistors Tr1 to Tr3. In the state table 2150, “H” represents a condition where the applied voltage is high (on), and “L” indicates a condition where the applied voltage is low (off).

For example, it is assumed that the switching circuit 2113 is set to “state 1” as an initial state. In this case, the switching circuit 2113 makes the voltage applied to the gate of the transistor Tr1 high and makes the voltages applied to the gates of the transistors Tr2 and Tr3 low. Accordingly, the drive current input to the input terminal 2111 is applied to the electrode 2131, and the LD 2141 (the active layer 2031) emits light.

Further, the switching circuit 2113 moves to “state 2” when the switching instruction information is input from the input terminal 2112 in “state 1”. In this case, the switching circuit 2113 makes the voltage applied to the gate of the transistor Tr2 high and makes the voltages applied to the gates of the transistors Tr1 and Tr3 low. Accordingly, the drive current input to the input terminal 2111 is applied to the electrode 2132, and the LD 2142 (the active layer 2032) emits light.

Further, the switching circuit 2113 moves to “state 3” when the switching instruction information is input from the input terminal 2112 in “state 2”. In this case, the switching circuit 2113 makes the voltage applied to the gate of the transistor Tr3 high and makes the voltages applied to the gates of the transistors Tr1 and Tr2 low. Accordingly, the drive current input to the input terminal 2111 is applied to the electrode 2133, and the LD 2143 (the active layer 2033) emits light.

Accordingly, the electric switch circuit 2013 may apply the drive current that is output from the driver circuit 2012 to any of the signal electrodes 1911 to 1913 of the LD chip 1910 and may switch the signal electrodes to which the drive current is applied when the switching instruction information is input.

### Fourth Embodiment

### Optical Amplifier According to Fourth Embodiment

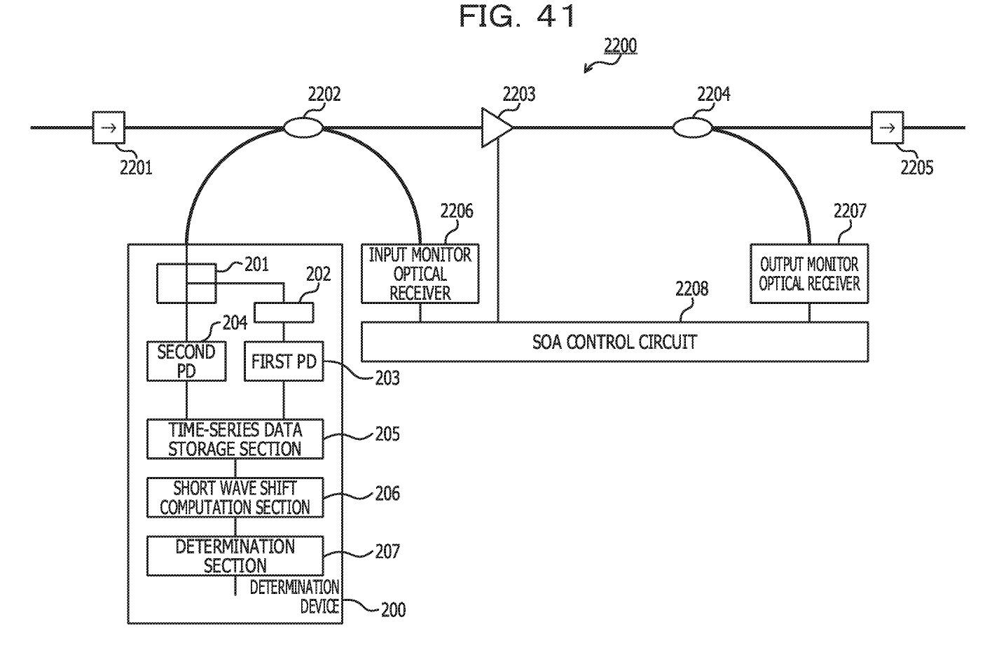

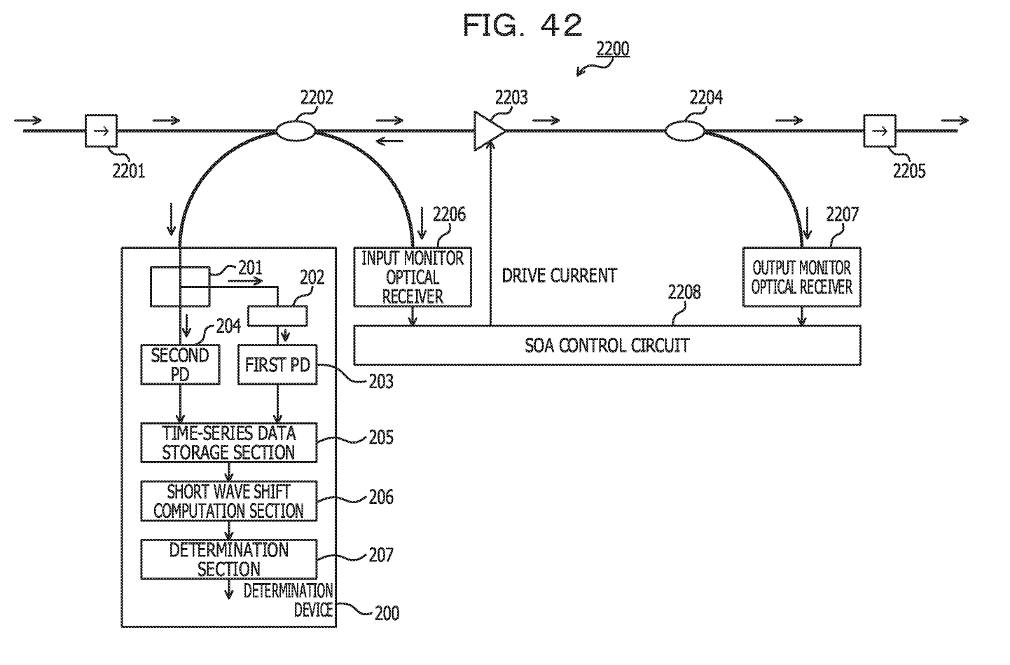

FIG. 41 illustrates an example of an optical amplifier according to the fourth embodiment. FIG. 42 illustrates an example of flows of light and electricity in the optical amplifier illustrated in FIG. 41. As illustrated in FIGS. 41 and 42, the optical amplifier 2200 according to the fourth embodiment includes an isolator 2201, an optical branch unit 2202, an SOA 2203, an optical branch unit 2204, and an isolator 2205. Further, the optical amplifier 2200 includes an input monitor optical receiver 2206, an output monitor optical receiver 2207, an SOA control circuit 2208, and the judgment device 200. The SOA control circuit 2208 may be realized by digital circuits such as the DSP and the FPGA, for example.

The isolator 2201 emits signal light that is incident on the optical amplifier 2200 to the optical branch unit 2202. Further, the isolator 2201 blocks light that is emitted from the optical branch unit 2202.

The optical branch unit 2202 is a two-input two-output splitting coupler. The optical branch unit 2202 splits the signal light that is emitted from the isolator 2201. The optical branch unit 2202 then emits beams of the split signal light to the SOA 2203 and the input monitor optical receiver 2206.

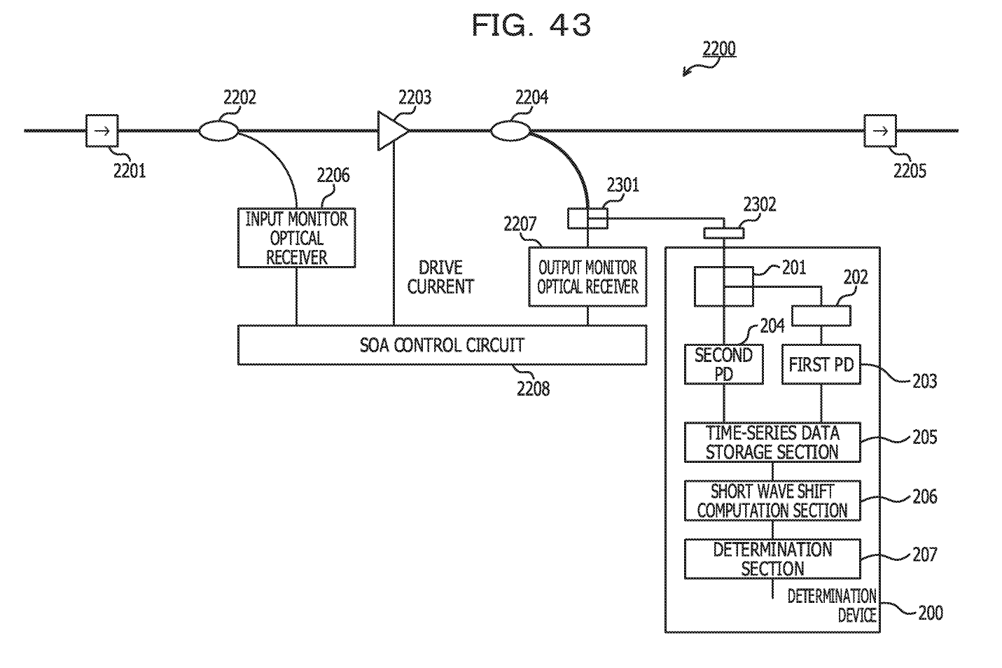

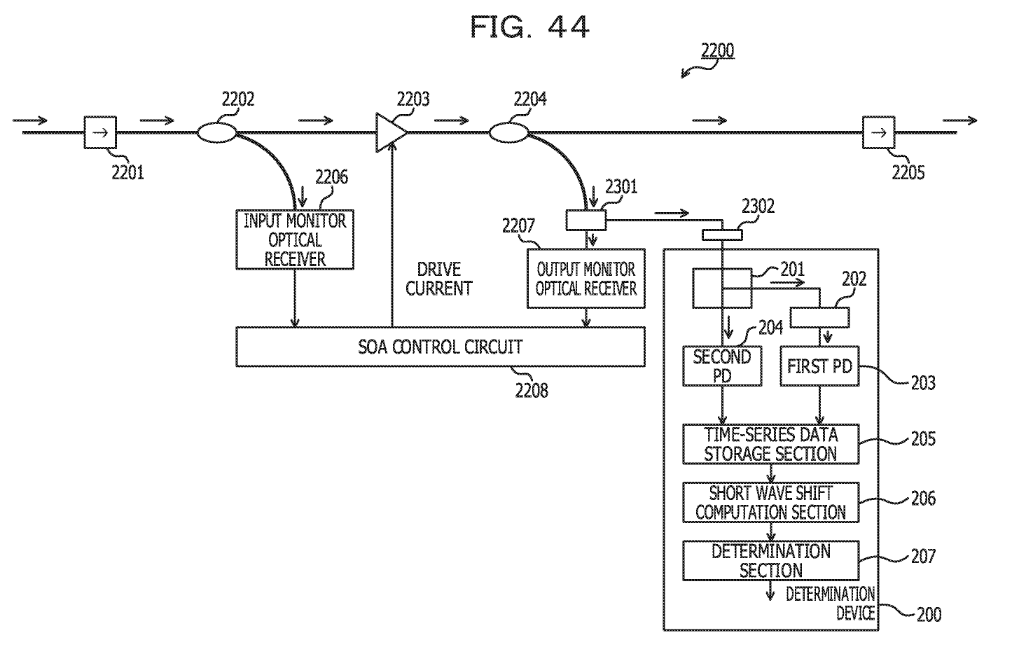

Further, the optical branch unit 2202 splits ASE light in a reverse direction that is emitted from the SOA 2203. The optical branch unit 2202 then emits beams of the split ASE light to the isolator 2201 and the judgment device 200. As described above, because the ASE light from the SOA 2203 in the reverse direction is incident on the judgment device 200 by using the two-input two-output optical branch unit 2202, an optical branch unit and an optical filter for splitting emission light from the SOA 2203 (for example, see FIGS. 43 and 44) may not be separately provided.

The SOA 2203 amplifies the signal light that is emitted from the optical branch unit 2202 in accordance with the drive current that is supplied from the SOA control circuit 2208. The SOA 2203 then emits the amplified signal light to the optical branch unit 2204. Further, the SOA 2203 is a semiconductor optical amplifier that contains aluminum or gallium arsenide in the active layer, for example. Further, the SOA 2203 produces the ASE light. The ASE light that is produced in the SOA 2203 is emitted to the optical branch unit 2202 and the optical branch unit 2204.

The optical branch unit 2204 splits the light that is emitted from the SOA 2203. The optical branch unit 2204 then emits beams of the split light to the isolator 2205 and the output monitor optical receiver 2207.

The isolator 2205 emits the signal light that is emitted from the optical branch unit 2204 to a rear stage of the optical amplifier 2200. Further, the isolator 2205 blocks light that is incident from an output end of the optical amplifier 2200.

The input monitor optical receiver 2206 receives the light that is emitted from the optical branch unit 2202. The input monitor optical receiver 2206 then outputs an electric signal that indicates the power of the received light to the SOA control circuit 2208. The output monitor optical receiver 2207 receives the light that is emitted from the optical branch unit 2204. The output monitor optical receiver 2207 then outputs an electric signal that indicates the power of the received light to the SOA control circuit 2208.

The SOA control circuit 2208 supplies the drive current to the SOA 2203 and thereby drives the SOA 2203. Further, the SOA control circuit 2208 controls the drive current that is supplied to the SOA 2203 and thereby controls light amplification by the SOA 2203.

For example, the SOA control circuit 2208 performs the APC in which the drive current is controlled based on the electric signal output from the output monitor optical receiver 2207 and the output power of the optical amplifier 2200 is thereby controlled to be maintained at a certain magnitude. Alternatively, the SOA control circuit 2208 performs the AGC in which the drive current is controlled based on the ratio between the electric signals that are output from the input monitor optical receiver 2206 and the output monitor optical receiver 2207 and the gain of the optical amplifier 2200 is thereby controlled to be maintained at a certain magnitude.

FIG. 43 illustrates a modification example of the optical amplifier according to the fourth embodiment. FIG. 44 illustrates an example of flows of light and electricity in the optical amplifier illustrated in FIG. 43. In FIGS. 43 and 44, the same reference numerals are provided to portions that are the same as the ones illustrated in FIGS. 41 and 42, and a description thereof will not be made. As illustrated in FIGS. 43 and 44, the optical amplifier 2200 according to the fourth embodiment may include an optical branch unit 2301 and an optical band-pass filter 2302 in addition to a configuration illustrated in FIGS. 41 and 42.

The optical branch unit 2204 emits beams of the split light to the isolator 2205 and the optical branch unit 2301. The optical branch unit 2301 splits the signal light that is emitted from the optical branch unit 2204. The optical branch unit 2301 then emits beams of the split light to the output monitor optical receiver 2207 and the optical band-pass filter 2302.

The output monitor optical receiver 2207 receives the light that is emitted from the optical branch unit 2301. The optical band-pass filter 2302 removes a signal band component of the light that is emitted from the optical branch unit 2301. The optical band-pass filter 2302 allows the light from which the signal band component is removed to be incident on the judgment device 200.

(Signal Light and ASE Light in SOA)

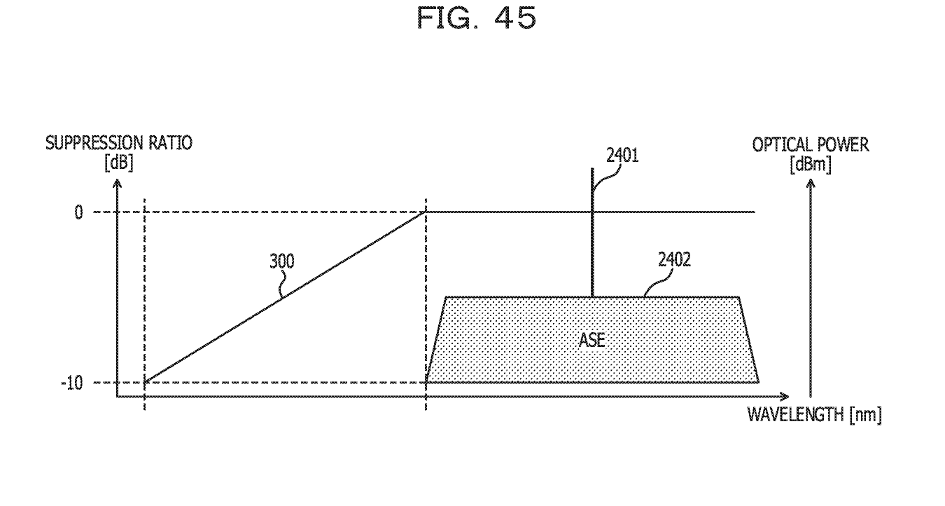

FIG. 45 illustrates an example of the signal light and the ASE light in the SOA. In FIG. 45, the same reference numerals are provided to portions that are the same as the ones illustrated in FIG. 9A, and a description thereof will not be made. In FIG. 45, the horizontal axis represents the wavelength [nm], and the vertical axis represents the suppression ratio [dB] and the optical power [dBm]. The spectrum 2401 represents the signal light that is an amplification target of the SOA 2203. The spectrum 2402 represents the ASE light in the SOA 2203.

As illustrated in FIG. 45, the wavelength transmission characteristic 300 may be considered as a characteristic in which a short wavelength side of the spectrum 2402 in an initial state of the ASE light of the SOA 2203 is rather contained in a band on the long wavelength side in which the transmittance is flat than a band in which the transmittance continuously decreases toward the short wavelength side, for example.

(Change in Transmittance in Wavelength Shift)

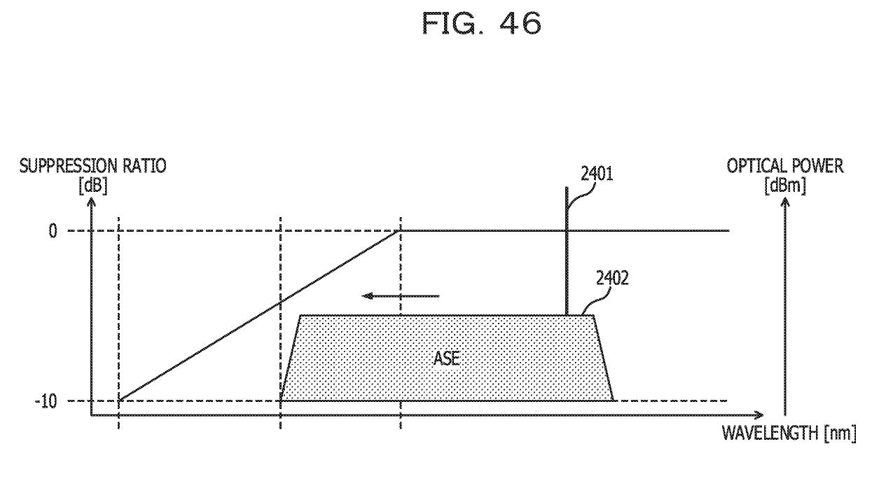

FIG. 46 illustrates an example of a change in the transmittance in the wavelength shift. In FIG. 46, the same reference numerals are provided to portions that are the same as the ones illustrated in FIG. 45, and a description thereof will not be made. When the wavelength of the ASE light of the SOA 2203 shifts toward the short wavelength side, the spectrum 2402 of the ASE light of the SOA 2203 shifts as illustrated in FIG. 46, for example.

The transmittance of the ASE light in the optical filter 202 thereby decreases. Thus, the power of light that is output from the optical filter 202 is reduced, and the value that is stored in the time-series data storage section 205 may be changed.

As described above, the fourth embodiment enables the detection of the shift of the output wavelength toward the short wavelength side that appears as the sign of the sudden failure due to oxidation of aluminum in an early stage in the SOA 2203 or the like that contains aluminum or gallium arsenide in the active layer. This enables an early prediction of the sudden failure of the SOA 2203 or the like. The early prediction of the sudden failure of the SOA 2203 or the like is enabled, and switching or the like of apparatuses prior to the sudden failure is thereby enabled, for example.

(Application to Screening)

The above-described judgment method is not limited to application during an operation of the optical communication system but may also be applied to screening in a shipping inspection of LDs at an LD vendor, for example. This screening is conducted as an inspection to in advance find and remove products to which the sudden failure occurs before shipping from the LD vendor, for example. The above-described judgment method enables the judgment about the sign of the sudden failure of the LD in an early stage. Accordingly, products to which the sudden failure occurs in the future may be detected by energization in a short time compared to a case where degradation of an optical output characteristic of the LD is monitored, for example.

For example, it is assumed that a guaranteed life of device (specification) of the shipped LDs is 10 years (87600 hours). In this case, in order to make a judgment about the life of the LD by degradation of the optical output characteristic (light efficiency) of the LD, an accelerated aging test that corresponds to 10 years is desired. For example, the accelerated aging test of 100 times acceleration uses 876 hours for the accelerated aging test that corresponds to 10 years.

However, in a case a judgment is made about the life of the LD by using the shift of the oscillation wavelength of the LD toward the short wavelength side, the accelerated aging test that corresponds to five years is adequate, for example. For example, the accelerated aging test of 100 times acceleration uses 438 hours for the accelerated aging test that corresponds to five years. Thus, the period desired for the screening in the shipping inspection may be reduced to about a half, for example.

Further, although the screening of the LD is described, a similar application may be made with screening of the SOA.

The semiconductor laser device, the optical amplifier, and the judgment method that are described above enable an early prediction of the sudden failure of the semiconductor optical device.

For example, the LD undergoes a phenomenon that the optical output is suddenly lost during an operation (sudden failure). This is a phenomenon that suddenly occurs without a sign and is different from a wear-out failure. A cause is generation of a non-light emission portion in the active layer due to an occurrence or an increase of the crystal defects. The crystal defect occurs depending on materials, manufacturing, operating conditions, and so forth of the LD. Even if the crystal defect is first formed in a point, disorganization of the crystal structure serves as stress to an adjacent normal crystal, and the crystal defect progresses to a point defect, a line defect, and a plane defect. Even if the first crystal defect is located outside the active layer, the crystal defect progresses due to straining between the crystals and may enter the active layer.

Disorganization of the crystal structure that once occurs in the active layer in the LD in an operation results in a severe phenomenon. Joule heat by an injection current and heat due to optical absorption are applied to an inside of the active layer, expansion of the non-light emission portion due to the crystal defects acceleratingly progresses, and further light absorption, heating, light absorption, and heating are repeated. Particularly, in a case where the active layer material contains aluminum, surface level formation due to oxidation of aluminum, non-light emission recombination, further disorganization of a crystal periodic structure, and further heating are repeated. This results in heating that exceeds the melting point of the semiconductor, collapse of a cavity structure, a sudden stop of laser oscillation, and the like. A mechanism of the sudden failure of the LD is as illustrated in FIG. 12, for example.

The dark line and the catastrophic optical damage are observed in a failure analysis of a product to which the sudden failure occurred, and the above-described mechanism that illustrates that the sudden failure is an acquired failure is proved. Further, it is known that removing faulty products in advance by the screening or the like is difficult. Further, the above-described sudden failure of the LD also occurs to the SOA that contains aluminum or gallium arsenide in the active layer.

There is a method of detecting degradation of the optical output power or efficiency degradation in such a case. For example, in a case where automatic current control (ACC) of the excitation current of the LD is performed, there is a method of monitoring forward light power of the LD, backward light power of the LD, and a ratio between those. Further, in a case where the auto power control (APC) of the optical output power by monitoring the backward light power or the forward light power of the LD is performed, there is a method of monitoring the drive current of the LD.

However, because the sudden failure is a phenomenon in which a transition time from optical output degradation to optical power termination is very short, the sudden failure may be detected immediately before the sudden failure by detection of optical output power degradation and efficiency degradation by those methods. However, the sign of the sudden failure may not be detected in an early stage.

Further, those methods have difficulty in distinction from a fluctuation of the optical output power due to the wear-out failure that is common aging degradation of the LD. Thus, it is considered that large optical power degradation and significant efficiency degradation that are features of the sudden failure are used as judgment references, for example. However, because the large optical power degradation and the significant efficiency degradation are phases that immediately lead to the sudden failure, the sign of the sudden failure may not be detected in an early stage.

On the other hand, in the above-described embodiments, a physical phenomenon due to oxidation of aluminum that is a root cause of the sudden failure is used as the judgment reference. That is, the phenomenon that occurs before the optical output power degradation and the efficiency degradation due to the sudden failure occur is observed, and faulty products to which the sudden failure occurs may thereby be separated in an earlier stage. For example, the shift of the output wavelength toward the short wavelength side that appears as the sign of the sudden failure due to oxidation of aluminum is detected in an early stage in the LD or the SOA that contains aluminum or gallium arsenide in the active layer, and the sudden failure may thereby be predicted in an early stage.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An optical amplifier comprising:
a semiconductor optical amplifier that contains aluminum or gallium arsenide in an active layer;
an optical branch circuit that emits beam to the semiconductor optical amplifier and splits an amplified spontaneous emission light emitted in a reverse direction from the semiconductor optical amplifier;
a detector that detects a shift of a wavelength of the amplified spontaneous emission light toward a short wavelength side; and
a judger that makes a judgment about a sign of a sudden failure of the semiconductor optical amplifier based on a detection result by the detector.

2. The optical amplifier according to claim 13, further comprising:
an optical branch that splits the amplified spontaneous emission light into a first light and a second light;
an optical filter that transmits the first light by a characteristic of transmitting prescribed wavelengths and outputs a transmitted light;
a first phase detector that receives the transmitted light that is transmitted through the optical filter; and
a second phase detector that is different from the first phase detector and receives the second light that is split by the optical branch, wherein the detector detects the shift of the wavelength of the amplified spontaneous emission light toward the short wavelength side based on a comparison result between received light intensities of the first phase detector and the second phase detector.

3. An optical amplifier comprising:
a semiconductor optical amplifier that contains aluminum or gallium arsenide in an active layer;
an optical branch circuit that splits a light emitted from the semiconductor optical amplifier;
an optical band-pass filter that removes a signal band component of the light;
a detector that detects a shift of a wavelength of the light from which the signal band component is removed toward a short wavelength side; and
a judger that makes a judgment about a sign of a sudden failure of the semiconductor optical amplifier based on a detection result by the detector.

4. The optical amplifier according to claim 13, further comprising:
an optical branch that splits the light, the light from which the signal band component is removed, into a first light and a second light;
an optical filter that transmits the first light by a characteristic of transmitting prescribed wavelengths and outputs a transmitted light;
a first phase detector that receives the transmitted light that is transmitted through the optical filter; and
a second phase detector that is different from the first phase detector and receives the second light that is split by the optical branch, wherein the detector detects the shift of the wavelength of the light from which the signal band component is removed toward the short wavelength side based on a comparison result between received light intensities of the first phase detector and the second phase detector.
